(19) United States
(12) Patent Application Publication
(10) Pub. No.: US 2026/0247600 A1
(43) Pub. Date: Aug. 20, 2026

(54) MEMORY DEVICE AND METHOD OF MANUFACTURING THE SAME

(71) Applicant: Kioxia Corporation, Tokyo (JP)

(72) Inventors: Masahiro KIYOTOSHI, Yokkaichi Mie (JP); Tomoya SANUKI, Yokohama Kanagawa (JP); Takayuki MIYAZAKI, Tokyo (JP); Keiji IKEDA, Yokkaichi Mie (JP); Kenichi HAGA, Yokkaichi Mie (JP)

(73) Assignee: Kioxia Corporation, Tokyo (JP)

(21) Appl. No.: 19/325,199

(22) Filed: Sep. 10, 2025

(30) Foreign Application Priority Data
Feb. 17, 2025 (JP) 2025-023784

(51) Int. Cl. H10B 12/00

(52) U.S. Cl. CPC H10B 12/30; H10B 12/03; H10B 12/05; H10B 12/50

(57) ABSTRACT

According to one embodiment, a memory device includes memory cells, a bit line and a word line. The memory cells include transistors stacked on a substrate in a first direction, and capacitors stacked on the substrate in the first direction and connected to the transistors. The bit line is connected to the memory cells. The word line is connected to the memory cells. The transistors include semiconductor layers extending in a second direction parallel to the substrate and gate electrodes provided to face the semiconductor layers. The bit line is connected to the semiconductor layers of the transistors and extends in the first direction. The word line includes the gate electrodes of the transistors and extends in a third direction parallel to the substrate and intersecting the second direction. The semiconductor layers and the bit line include conductive oxide.

### CROSS-REFERENCE TO RELATED APPLICATIONS

This application is based upon and claims the benefit of priority from Japanese Patent Application No. 2025-023784, filed Feb. 17, 2025, the entire contents of which are incorporated herein by reference.

### FIELD

Embodiments described herein relate generally to a memory device and a method for manufacturing the same.

### BACKGROUND

A memory device including memory cells arranged three-dimensionally is known. Examples of the memory device include a dynamic random access memory (DRAM).

### BRIEF DESCRIPTION OF THE DRAWINGS

FIG. 1 is a block diagram illustrating a configuration of a memory device according to an embodiment.

FIG. 2 is a circuit diagram illustrating a configuration of a part of a memory cell array according to the embodiment.

FIG. 3 is a circuit diagram illustrating a configuration of the memory cell of the memory cell array according to the embodiment.

FIG. 4 is a perspective view illustrating a structure of the memory cell array according to the embodiment.

FIGS. 5 to 32 are perspective views illustrating a method of manufacturing the memory cell array according to the embodiment.

FIGS. 33 to 35 are perspective views illustrating a method of manufacturing the memory cell array of Modification 1 according to the embodiment.

FIGS. 36 to 38 are perspective views illustrating a method of manufacturing the memory cell array of Modification 2 according to the embodiment.

FIGS. 39 to 44 are cross-sectional views illustrating a method of manufacturing the memory cell array of Modification 3 according to the embodiment.

FIGS. 45 to 48 are perspective views illustrating a method of manufacturing a memory cell array using an NPOC stacked structure according to Modification 3 of the embodiment.

FIG. 49 is a cross-sectional view illustrating a first example of a layout of a bit line selection transistor in the memory device according to the embodiment.

FIG. 50 is a cross-sectional view illustrating a second example of the layout of the bit line selection transistor in the memory device according to the embodiment.

FIG. 51 is a cross-sectional view illustrating a third example of the layout of the bit line selection transistor in the memory device according to the embodiment.

### DETAILED DESCRIPTION

In general, according to one embodiment, a memory device includes a plurality of memory cells, a bit line and a word line. The plurality of memory cells include a plurality of transistors stacked on a substrate in a first direction, and a plurality of capacitors stacked on the substrate in the first direction and connected to the plurality of transistors. The bit line is connected to the plurality of memory cells. The word line is connected to the plurality of memory cells. The plurality of transistors include semiconductor layers extending in a second direction parallel to the substrate and gate electrodes provided to face the semiconductor layers. The bit line is connected to the semiconductor layers of the plurality of transistors and extends in the first direction. The word line includes the gate electrodes of the plurality of transistors and extends in a third direction parallel to the substrate and intersecting the second direction. The semiconductor layers and the bit line include conductive oxide.

According to one embodiment, A method for manufacturing a memory device including memory cells including transistors and capacitors, a word line, and a bit line, the method comprises alternately stacking first sacrificial layers and second sacrificial layers; forming a first slit at one ends of the first sacrificial layers and the second sacrificial layers; forming sacrificial semiconductor layers corresponding to semiconductor layers of the transistors on one end side of the second sacrificial layers by removing one end side of the first sacrificial layers and removing a part of one end side of the second sacrificial layers; forming the word line crossing the sacrificial semiconductor layers; forming a sacrificial bit line corresponding to the bit line at one end of the sacrificial semiconductor layer; forming a second slit at the other ends of the first sacrificial layers and the second sacrificial layers; removing the other end side of the second sacrificial layers and forming the capacitors at the other ends of the sacrificial semiconductor layers; and replacing the sacrificial semiconductor layers and the sacrificial bit line with a semiconductor material layer.

In the following description, components having the same function and configuration are denoted by the same reference numerals. In addition, the following embodiment exemplifies an apparatus and a method for embodying the technical idea of this example embodiment, and does not identify the material, shape, structure, arrangement, and the like of the components as follows.

The drawings are schematic or conceptual. Dimensions, ratios, and the like of each drawing do not necessarily coincide with actual ones. An XYZ orthogonal coordinate system is used in some drawings illustrating the structure. An X axis extends in an X direction. A Y axis extends in a Y direction. A Z axis extends in a Z direction. The X direction and the Y direction are directions orthogonal to each other. The Z direction is orthogonal to each of the X direction and the Y direction, and corresponds to a vertical direction with respect to a surface of a semiconductor substrate. In addition, a side having larger coordinates on the X axis (X direction), the Y axis (Y direction), or the Z axis (Z direction) may be referred to as a positive direction, and a side having smaller coordinates may be referred to as a negative direction. The positive direction of the Z axis may be referred to as an upper side, and the negative direction may be referred to as a lower side. The positive direction of the X axis or the Y axis may be referred to as a right side, and the negative direction may be referred to as a left side.

Hereinafter, a memory device according to an embodiment will be described.

### 1. Configuration

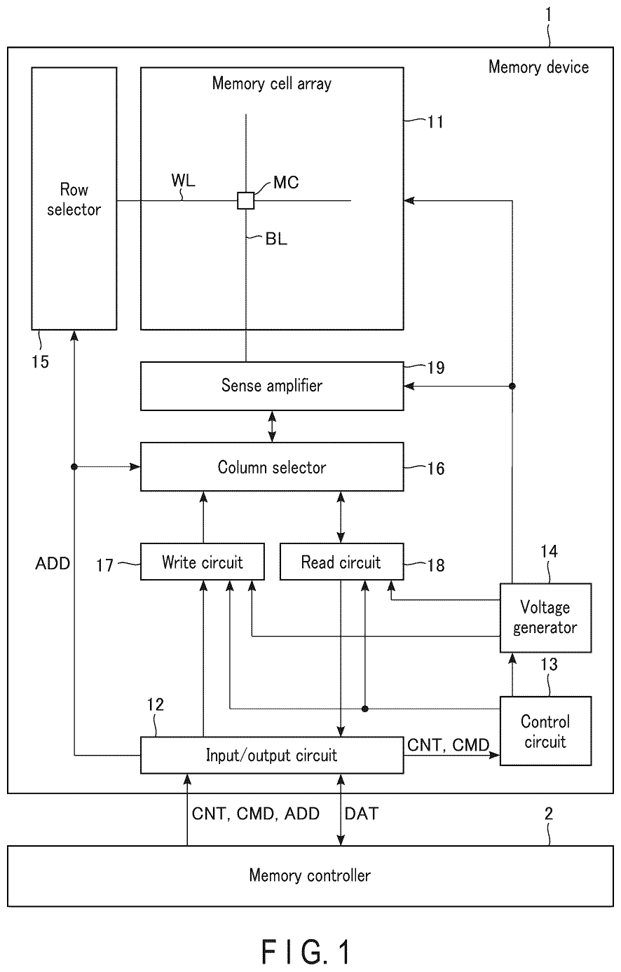

First, a configuration of a memory device according to the embodiment will be described with reference to FIG. 1. FIG. 1 is a block diagram illustrating the configuration of the memory device according to the embodiment. A memory device 1 is a device that stores data. The memory device 1 is connected to a memory controller 2, and is configured to be able to read and write data based on an order from the memory controller 2.

The memory device 1 includes a memory cell array 11, an input/output circuit 12, a control circuit 13, a voltage generator 14, a row selector 15, a column selector 16, a write circuit 17, a read circuit 18, and a sense amplifier 19.

The memory cell array 11 includes a plurality of memory cells MC, a plurality of word lines WL, and a plurality of bit lines BL. Each memory cell MC can store 1-bit data. Each memory cell MC is connected to one bit line BL and one word line WL. The memory cell MC is connected between the bit line BL and a plate line (not illustrated). The word line WL is associated with a row. The bit line BL is associated with a column. One memory cell MC is specified by selection of one row and selection of one column.

The input/output circuit 12 is a circuit that inputs and outputs data and signals. The input/output circuit 12 receives a control signal CNT, a command CMD, an address signal ADD, and data DAT from the outside of the memory device 1, for example, from the memory controller 2. The input/output circuit 12 inputs and outputs the data DAT. In a case where the data is written in the memory device 1, the data DAT is write data. In a case where data is read in the memory device 1, the data DAT is read data.

The control circuit 13 is a circuit that controls the operation of the memory device 1. The control circuit 13 receives the command CMD and the control signal CNT from the input/output circuit 12. The control circuit 13 controls the write circuit 17 and the read circuit 18 based on the control instructed by the command CMD and the control signal CNT.

The voltage generator 14 is a circuit that generates various voltages used in the memory device 1. The voltage generator 14 generates a plurality of voltages having different magnitudes under the control of the control circuit 13. The voltage generator 14 supplies the generated voltage to the memory cell array 11, the write circuit 17, the read circuit 18, and the sense amplifier 19.

The row selector 15 is a circuit that selects a row of the memory cell MC. The row selector 15 receives the address signal ADD from the input/output circuit 12. The row selector 15 uses the voltage received from the voltage generator 14 to select one word line WL associated with the row specified by the address signal ADD.

The column selector 16 is a circuit that selects a column of the memory cell MC. The column selector 16 receives an address signal ADD from the input/output circuit 12. The column selector 16 uses the voltage received from the voltage generator 14 to select the bit line BL associated with the column specified by the address signal ADD.

The write circuit 17 is a circuit that performs control for writing data to the memory cell MC. The write circuit 17 receives write data from the input/output circuit 12. The write circuit 17 supplies the voltage received from the voltage generator 14 to the column selector 16 based on the control of the control circuit 13 and the write data.

The read circuit 18 is a circuit that performs control for reading data from the memory cell MC. The read circuit 18 supplies the voltage received from the voltage generator 14 to the column selector 16 under the control of the control circuit 13. The read circuit 18 supplies a plurality of control signals for data reading to the sense amplifier 19.

The sense amplifier 19 is a circuit for determining data stored in the memory cell MC. The sense amplifier 19 includes a plurality of sense amplifier circuits. The sense amplifier 19 receives a plurality of voltages from the voltage generator 14 and operates using the received voltages. During data reading, the sense amplifier 19 amplifies a potential on the bit line BL in order to determine data stored in the memory cell MC from which data is to be read. The determined data is supplied to the input/output circuit 12.

### 1.1. Circuit Configuration of Memory Cell Array

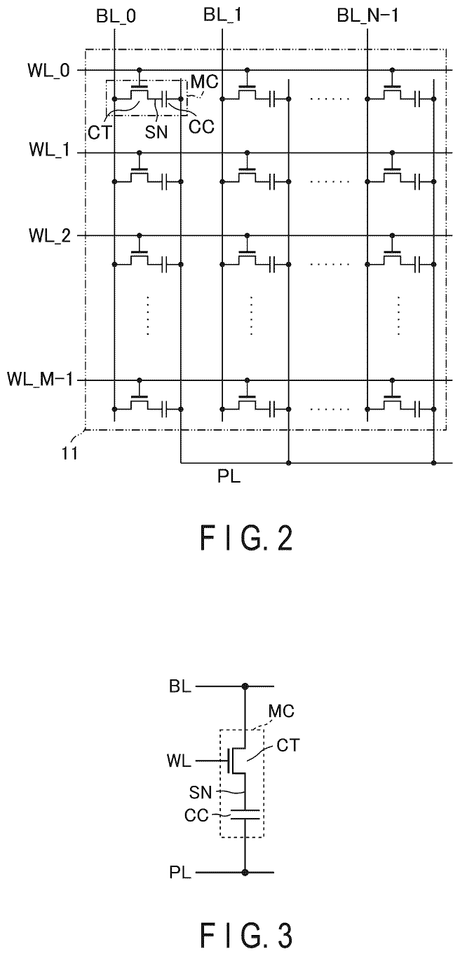

Next, the memory cell array 11 in the memory device 1 of the embodiment will be described with reference to FIG. 2. FIG. 2 is a circuit diagram showing a configuration of a part of the memory cell array 11 in the memory device of the embodiment. FIG. 3 is a circuit diagram illustrating a configuration of the memory cell MC in the memory cell array 11.

As illustrated in FIG. 2, the memory cell array 11 includes a plurality of memory cells MC. In the memory cell array 11, M word lines WL_0 to WL_M-1, N bit lines BL_0 to BL_N-1, and a plate line PL are arranged. M and N are integers of 0 or more.

As illustrated in FIG. 3, each memory cell MC is connected to one word line WL and one bit line BL. Each memory cell MC is further connected to the plate line PL.

Each memory cell MC includes a cell transistor CT and a cell capacitor (alternatively, a storage element) CC. The cell transistor CT is, for example, an n-type MOS field effect transistor (Metal Oxide Semiconductor Field Effect Transistor: MOSFET). Hereinafter, one of the source and the drain of the transistor may be referred to as one end of the transistor, and the other may be referred to as the other end of the transistor.

One end of the cell capacitor CC is connected to the plate line PL. The other end of the cell capacitor CC is connected to one end of the cell transistor CT. A node to which the cell capacitor CC and the cell transistor CT are connected may be referred to as a storage node SN. The other end of the cell transistor CT is connected to one bit line BL. Further, the gate of the cell transistor CT is connected to one word line WL.

The cell capacitor CC stores data using the charge accumulated in the storage node SN connected to the cell transistor CT.

A state of whether the storage node SN accumulates charges is associated with a state in which the memory cell MC stores “1” data or “0” data. Hereinafter, as an example, a state in which the potential of the storage node SN is charged to a relatively positive potential with respect to the potential of the plate line PL is treated as a state in which the memory cell MC stores “1” data, and a state in which the potential of the storage node SN is charged to a relatively negative potential with respect to the potential of the plate line PL is treated as a state in which the memory cell MC stores “0” data.

The semiconductor layer configuring a part of the cell transistor CT provides at least a region (channel region) in which a channel is formed. The semiconductor layer contains conductive oxide (alternatively, oxide semiconductor) or is substantially made of conductive oxide. In the present specification and claims, “substantially made of” means that an element “substantially made of” is permitted to contain unintended impurities. The conductive oxide refers to oxide having characteristics of a semiconductor (alternatively, a conductor). Examples of the conductive oxide include an oxide containing one or more of indium (In), gallium (Ga), aluminum (Al), zinc (Zn), and tin (Sn). In one example, the conductive oxide includes, for example, In, Ga, Zn, and O (oxygen). In another example, the conductive oxide includes In, Al, Zn, and O.

### 1.2. Structure of Memory Cell Array

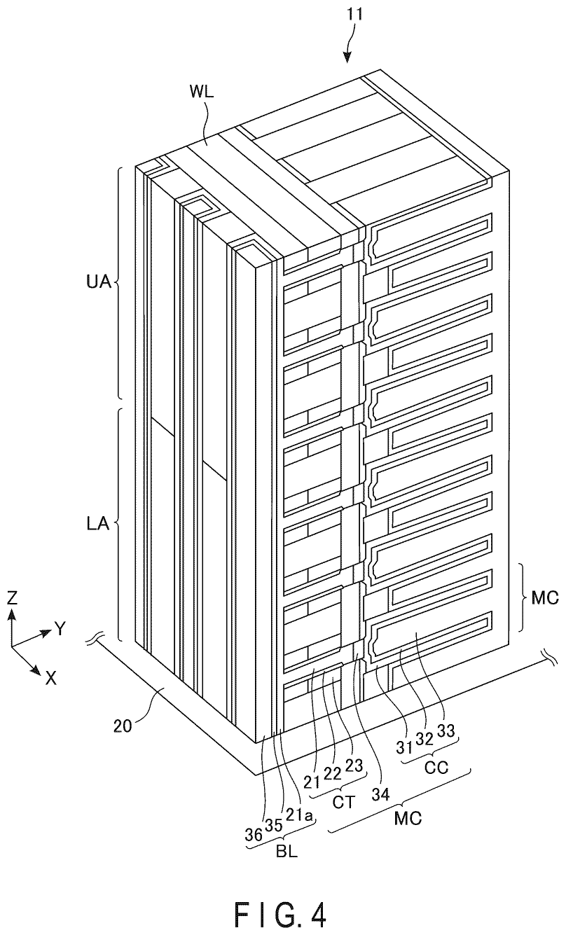

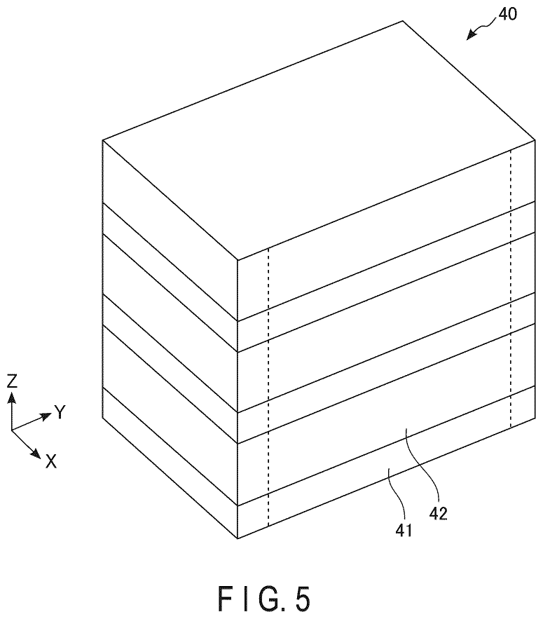

Next, a structure of the memory cell array 11 in the memory device 1 according to the embodiment will be described with reference to FIG. 4. FIG. 4 is a perspective view illustrating a structure of the memory cell array 11 in the memory device according to the embodiment. FIG. 4 illustrates a structure in which two arrays of the lower layer array LA and the upper layer array UA are stacked.

As illustrated in FIG. 3, a lower layer array LA and an upper layer array UA are provided on the semiconductor substrate 20. The lower layer array LA is provided above the semiconductor substrate 20, and the upper layer array UA is provided on the lower layer array LA.

The lower layer array LA includes a plurality of memory cells MC arranged three-dimensionally. The plurality of memory cells MC is arranged in the X direction and the Y direction, and the memory cells MC arranged in the X direction and the Y direction are stacked in the Z direction. In FIG. 4, the plurality of memory cells MC arranged in the Y direction is omitted, and only one memory cell MC is shown. Similarly, the upper layer array UA includes a plurality of memory cells MC arranged three-dimensionally.

Hereinafter, the memory cells MC included in the lower layer array LA and the upper layer array UA will be described. As described above, the memory cell MC includes the cell transistor CT and the cell capacitor CC.

The cell transistor CT includes a semiconductor layer (alternatively, a channel layer) 21, a gate insulating layer 22, and a gate electrode layer 23. The semiconductor layer 21 extends in the Y direction. The semiconductor layer 21 contains, for example, a conductive oxide. The conductive oxide contains at least one of In, Ga, Zn, Sn, Ti, Mo, and W.

The gate insulating layer 22 is provided on the lower surface, the upper surface, and the side surface of the semiconductor layer 21. The gate electrode layer 23 is provided on the lower surface, the upper surface, and the side surface of the gate insulating layer 22. That is, the gate insulating layer 22 is provided in such a way as to cover the semiconductor layer 21. The gate electrode layer 23 is provided in such a way as to cover the gate insulating layer 22. The gate electrode layer 23 is disposed on the lower surface, the upper surface, and the side surface of the semiconductor layer 21 with the gate insulating layer 22 interposed therebetween. The gate electrode layer 23 extends in the X direction and configures the word line WL.

The cell capacitor CC includes a first electrode layer 31, a second electrode layer 33, and an insulating layer 32 between the first electrode layer 31 and the second electrode layer 33. The first electrode layer 31 is provided at one end of the semiconductor layer 21 via the conductive layer 34. That is, the first electrode layer 31 is connected to the semiconductor layer 21 via the conductive layer 34. The first electrode layer 31 includes, for example, a conductive layer such as a titanium nitride layer. The conductive layer 34 contains, for example, conductive oxide such as indium tin oxide (ITO).

The second electrode layer 33 is provided in such a way as to face the first electrode layer 31 via the insulating layer 32. The second electrode layer 33 is shared by the cell capacitors CC included in the plurality of memory cells MC. The second electrode layer 33 is connected to the plate line PL (not illustrated). The second electrode layer 33 includes, for example, a conductive layer such as a titanium nitride layer.

The three conductive layers 21a, 35, and 36 are provided at the other end of the semiconductor layer 21. That is, the conductive layers 21a, 35, and 36 are connected to the semiconductor layer 21. The conductive layers 21a and 35 are provided in a sheet shape, and the conductive layer 36 is provided in a linear shape. The conductive layers 21a, 35, and 36 extend in the Z direction. The conductive layers 21a, 35, and 36 configure the bit line BL. Note that the conductive layer 21a may be formed integrally with the semiconductor layer 21. For example, the semiconductor layer 21 and the conductive layer 21a may be made of the same conductive oxide through the same manufacturing process.

In the lower layer array LA (alternatively, the upper layer array UA), the number of the plurality of stacked cell capacitors CC is equal to or less than the number of the plurality of stacked cell transistors CT.

Here, an example in which a two-layer array of the lower layer array LA and the upper layer array UA is stacked has been described, but a case where an array of three or more layers is stacked has a similar structure.

### 2. Manufacturing Method

Next, a method of manufacturing the memory cell array 11 in the memory device 1 of the embodiment will be described with reference to FIGS. 5 to 32. FIGS. 5 to 32 are perspective views illustrating a method of manufacturing the memory cell array 11 in the memory device according to the embodiment.

First, as illustrated in FIG. 5, a mold layer 40 in which first sacrificial layers (for example, silicon nitride layers) 41 and second sacrificial layers (for example, amorphous or polycrystalline silicon layers) 42 are alternately stacked in the Z direction is formed.

Specifically, the first sacrificial layer 41 is formed on a semiconductor substrate (not illustrated) using, for example, chemical vapor deposition (CVD). Subsequently, the second sacrificial layer 42 is formed on the first sacrificial layer 41 by using, for example, CVD. Further, the first sacrificial layer 41 is formed on the second sacrificial layer 42, and the second sacrificial layer 42 is formed on the first sacrificial layer 41. Similarly, the formation of the first sacrificial layers 41 and the second sacrificial layers 42 is alternately repeated. As a result, the mold layer 40 as illustrated in FIG. 5 is formed.

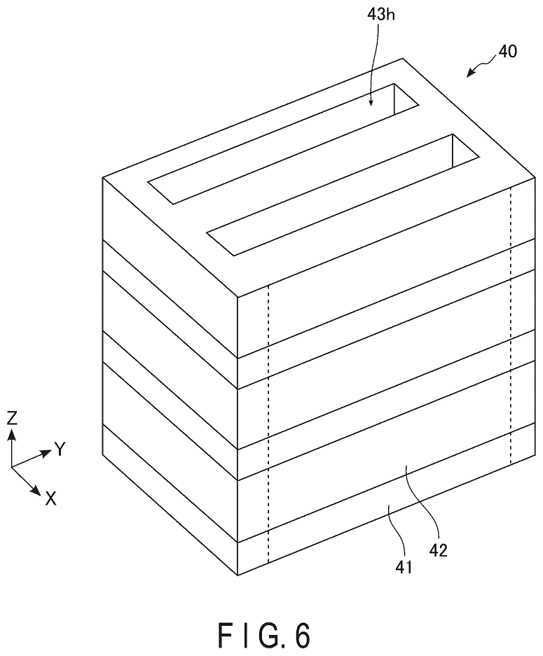

Next, as illustrated in FIG. 6, holes 43h for forming an insulating layer for separating the active area of the cell transistor CT are formed in the mold layer 40.

Specifically, the holes 43h extending in the Y direction and the Z direction are formed in the mold layer 40 using, for example, reactive ion etching (RIE).

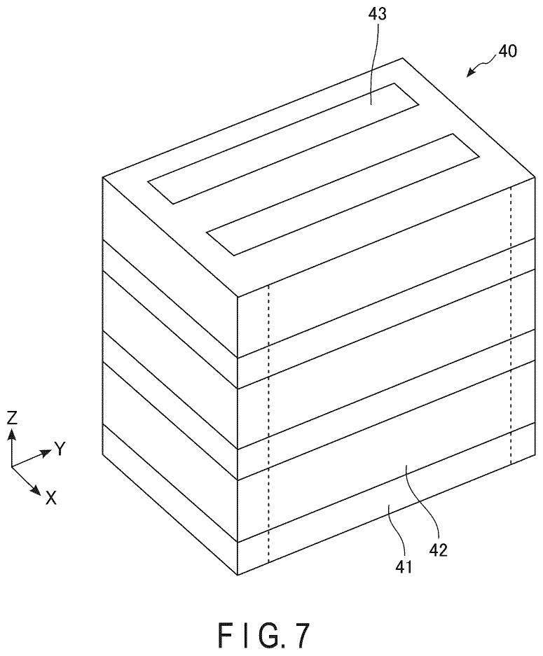

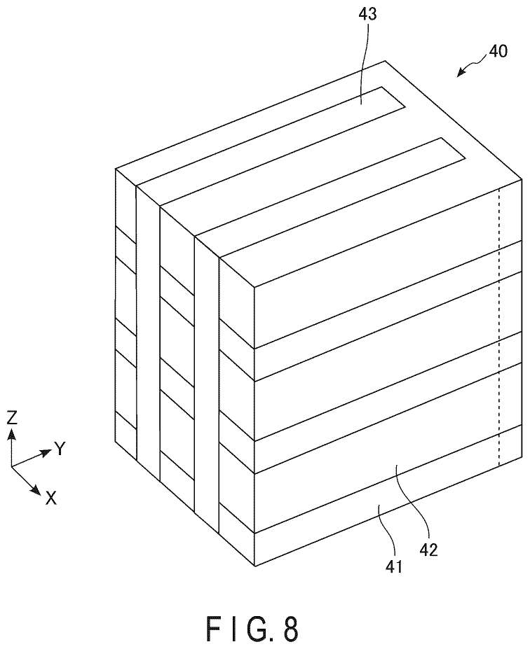

Next, as illustrated in FIG. 7, insulating layers (for example, silicon oxide layers) 43 for separating an active area of the cell transistor CT are formed in the mold layer 40.

Specifically, the insulating layers 43 are embedded in holes 43h formed in the mold layer 40 using, for example, CVD or atomic layer deposition (ALD). Subsequently, the excessive insulating layers 43 are removed. As a result, as illustrated in FIG. 7, the insulating layers 43 that separate the active area are formed in the mold layer 40.

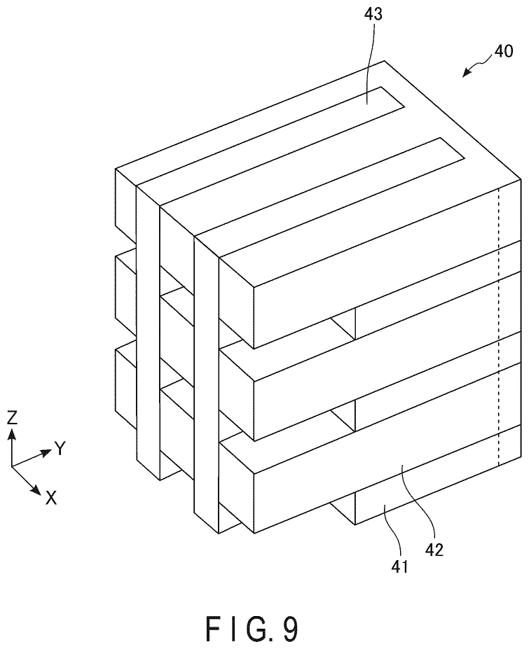

Next, as illustrated in FIG. 8, the stack of the first sacrificial layers 41 and the second sacrificial layers 42 at one end portion of the mold layer 40 in the negative direction of the Y direction is removed. Hereinafter, in this process, a stacked surface of the first sacrificial layers 41 and the second sacrificial layers 42 from which one end portion is removed is referred to as a first slit surface.

Next, as illustrated in FIG. 9, parts of the first sacrificial layers 41 are removed from the first slit surface.

Specifically, parts of the first sacrificial layers 41 are removed by etching from one end side of the first sacrificial layers 41 in the negative direction in the Y direction, and the first sacrificial layers 41 are retracted. In this process, the first sacrificial layers 41 are removed up to before a region where the cell capacitors CC are formed.

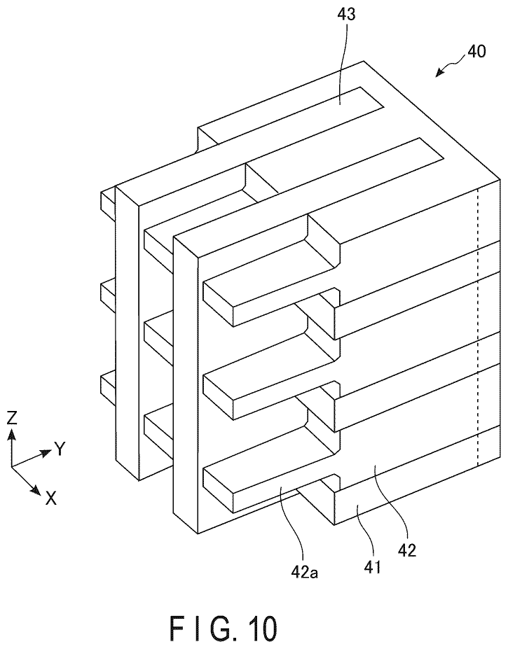

Next, as illustrated in FIG. 10, the second sacrificial layers 42 exposed by the removal of the first sacrificial layers 41 are trimmed. Hereinafter, parts of the trimmed second sacrificial layers 42 are referred to as beam portions 42a.

Specifically, the second sacrificial layers 42 exposed by the retreat of the first sacrificial layers 41 are trimmed, and the thickness of the beam portions 42a in the Z direction is reduced.

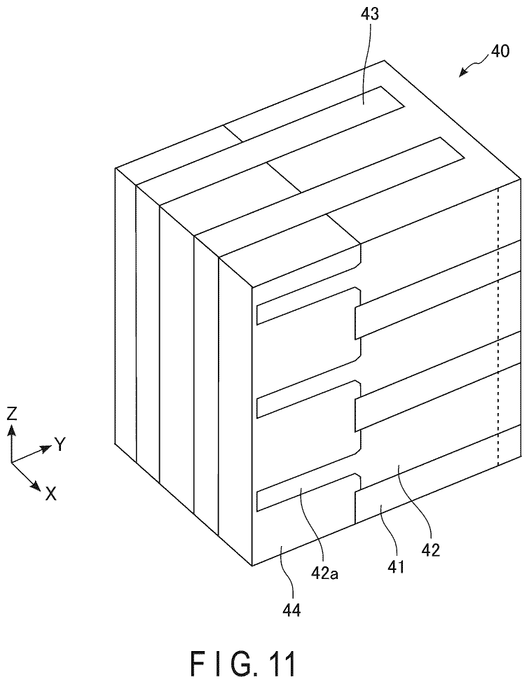

Next, as illustrated in FIG. 11, insulating layers (for example, silicon oxide layers) 44 are formed in such a way as to cover the beam portions 42a of the trimmed second sacrificial layers 42.

Specifically, the beam portions 42a of the trimmed second sacrificial layers 42 are filled with the insulating layers 44 by using, for example, CVD. Subsequently, the excessive insulating layers 44 are removed. As a result, as illustrated in FIG. 11, the insulating layers 44 are formed in the beam portions 42a of the second sacrificial layers 42.

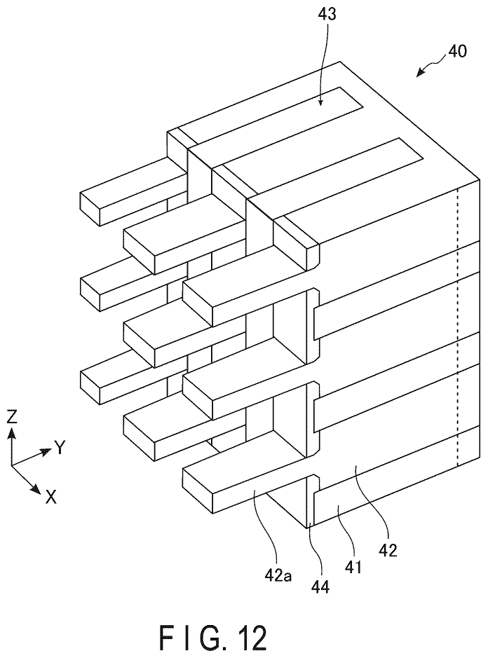

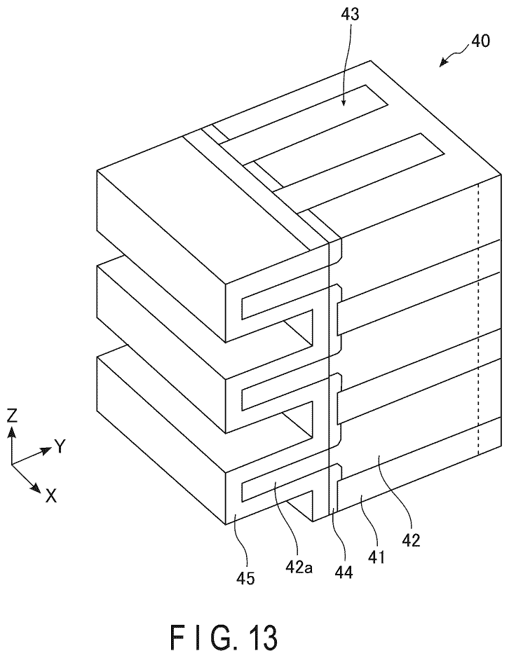

Next, as illustrated in FIG. 12, parts of the insulating layers 44 are removed to expose the beam portions 42a of the second sacrificial layers 42.

Specifically, parts of the insulating layers 44 are removed by etching from one end side of the insulating layers 44 in the negative direction in the Y direction, and the insulating layers 44 are retracted. As a result, as illustrated in FIG. 12, the beam portions 42a of the second sacrificial layers 42 are exposed.

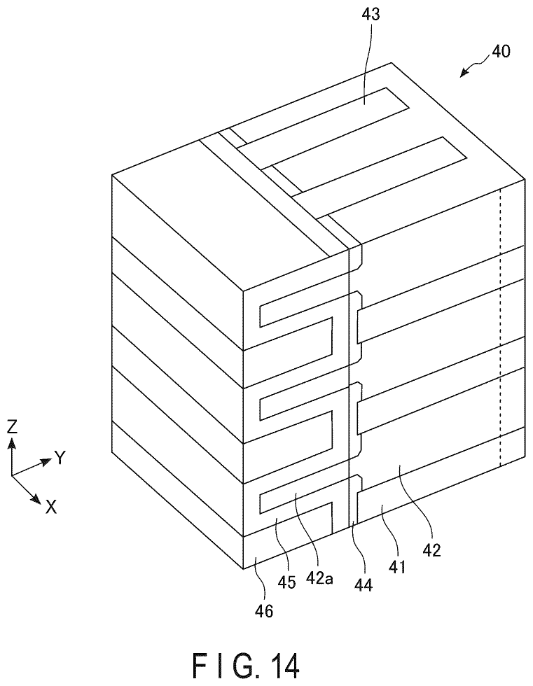

Next, as illustrated in FIG. 13, an insulating layer (for example, a silicon nitride layer) 45 is formed on the exposed beam portions 42a of the second sacrificial layers 42.

Specifically, the insulating layer 45 is formed on the upper surface, the lower surface, and the side surface of the beam portions 42a of the second sacrificial layers 42 by using, for example, CVD or ALD. In this process, the insulating layer 45 is also embedded between the adjacent beam portions 42a in the X direction.

Next, as illustrated in FIG. 14, insulating layers (for example, silicon oxide layers) 46 are formed in spaces where the insulating layer 45 is not formed in the Z direction.

Specifically, the insulating layers 46 are buried in spaces where the insulating layers 45 are not formed between the beam portions 42a of the second sacrificial layers 42 by using, for example, CVD. Subsequently, the excessive insulating layers 46 are removed. As a result, as illustrated in FIG. 14, the insulating layer 46 is formed in spaces where the insulating layer 45 is not formed.

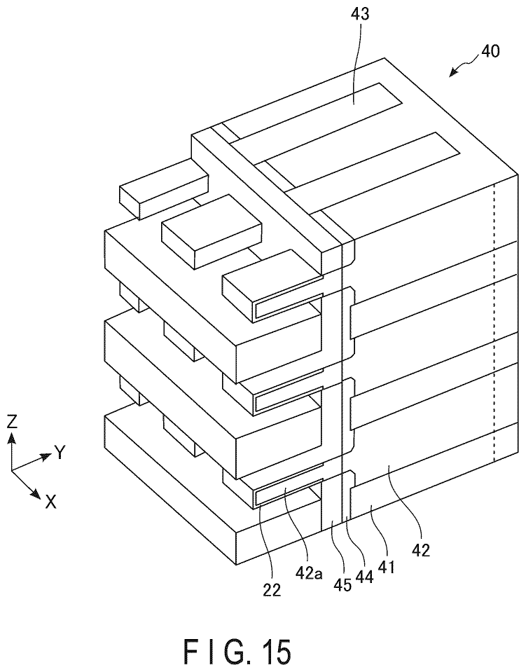

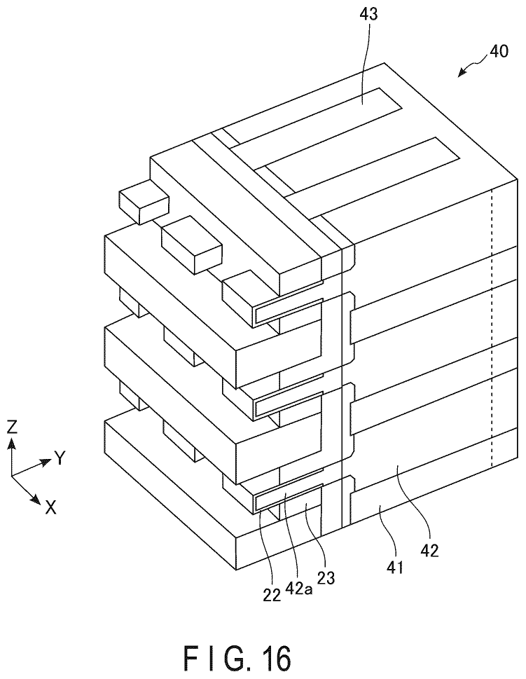

Next, as illustrated in FIG. 15, parts of the insulating layer 45 are removed, and gate insulating layers (for example, silicon oxide layers) 22 are formed on the exposed beam portions 42a of the second sacrificial layers 42. The gate insulating layers 22 function as gate insulating layers of the cell transistor CT. The gate insulating layers 22 are formed in such a way as to cover the beam portions 42a.

Specifically, parts of the insulating layer 45 are removed by etching from one end side of the insulating layer 45 in the negative direction of the Y direction to expose the beam portions 42a of the second sacrificial layers 42. Subsequently, the exposed upper surfaces, lower surfaces, and side surfaces of the beam portions 42a of the second sacrificial layers 42 are oxidized using, for example, a thermal oxidation method to form gate insulating layers 22. As a result, as illustrated in FIG. 15, the beam portions 42a of the second sacrificial layers 42 are covered with the gate insulating layers 22.

Next, as illustrated in FIG. 16, gate electrode layers 23 are formed on the gate insulating layers 22 covering the beam portions 42a of the second sacrificial layers 42. The gate electrode layers 23 function as gate electrode layers of the cell transistor CT. The gate electrode layers 23 are formed in such a way as to cover the gate insulating layers 22 on the beam portions 42a. The gate electrode layers 23 include, for example, a metal layer such as tungsten.

Specifically, the gate electrode layers 23 are formed on the gate insulating layers 22 covering the upper surfaces, the lower surfaces, and the side surfaces of the beam portions 42a of the second sacrificial layers 42. The gate electrode layer 23 extends in the X direction and configures the word line WL.

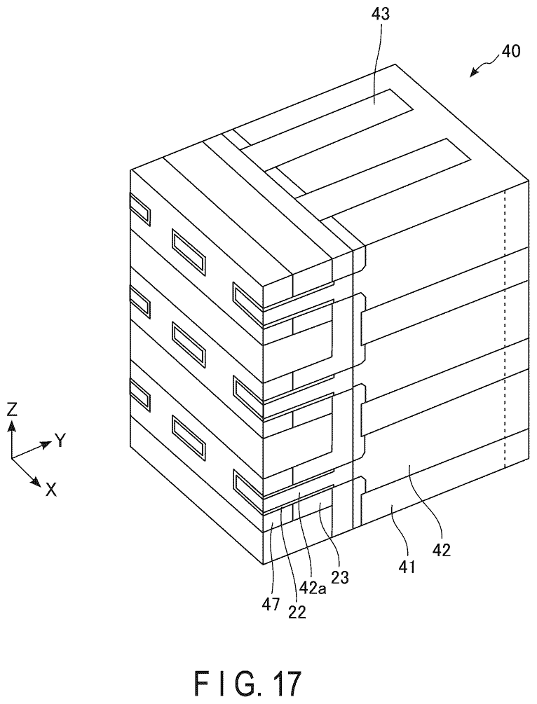

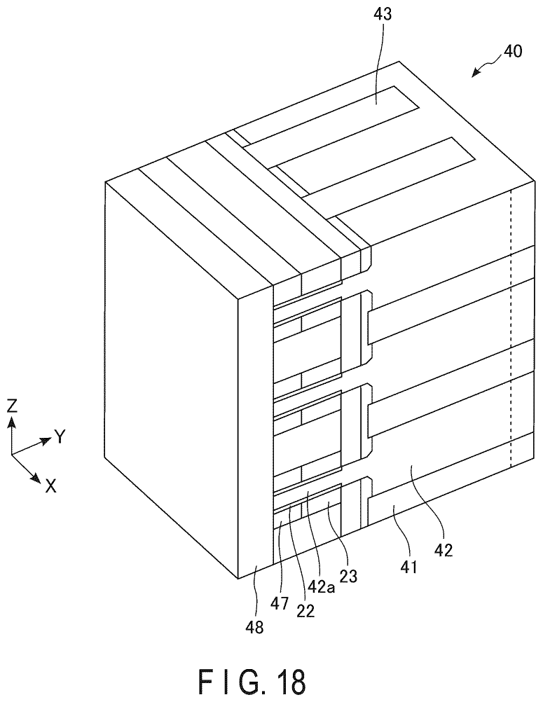

Next, as illustrated in FIG. 17, insulating layers (for example, silicon nitride layers) 47 are formed on the beam portions 42a of the second sacrificial layers 42 in which the gate electrode layers 23 are not formed. Further, ends of the beam portions 42a of the second sacrificial layers 42 are exposed.

Specifically, insulating layers 47 are embedded on the beam portions 42a of the second sacrificial layers 42 by using, for example, CVD or ALD. Subsequently, the beam portions 42a of the second sacrificial layers 42 and one end portions of the insulating layers 47 in the negative direction of the Y direction are removed by etching, and the end portions of the beam portions 42a of the second sacrificial layers 42 are exposed.

Next, as illustrated in FIG. 18, a sacrificial layer (for example, a polycrystalline silicon layer) 48 is formed on the surface of one end of the mold layer 40 in the negative direction of the Y direction.

Specifically, the sacrificial layer 48 is buried in the exposed end portion of the beam portions 42a and the insulating layers 47 by using, for example, CVD or ALD. Subsequently, the excessive sacrificial layer 48 is removed.

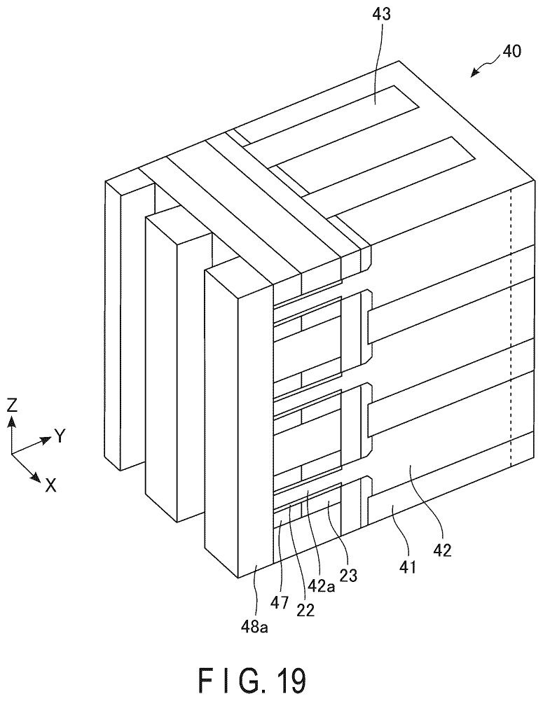

Next, as illustrated in FIG. 19, sacrificial layers 48a extending linearly in the Z direction are formed.

Specifically, the sacrificial layer 48 is removed in the Z direction using, for example, RIE to form the linear sacrificial layers 48a extending in the Z direction.

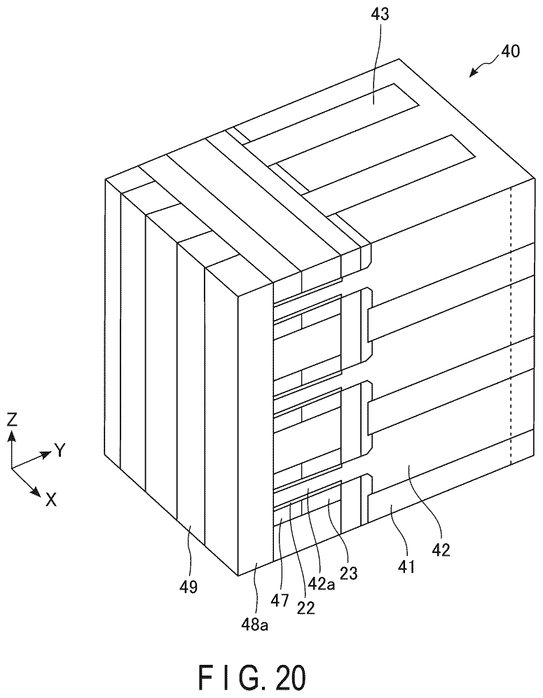

Next, as illustrated in FIG. 20, insulating layers (for example, silicon oxide layers) 49 are formed in grooves between the sacrificial layers 48a.

Specifically, the insulating layers 49 are embedded in the grooves between the adjacent sacrificial layers 48a using, for example, CVD or ALD. Subsequently, the excessive insulating layers 49 are removed. As a result, as illustrated in FIG. 20, the insulating layers 49 extending in the Z direction are formed.

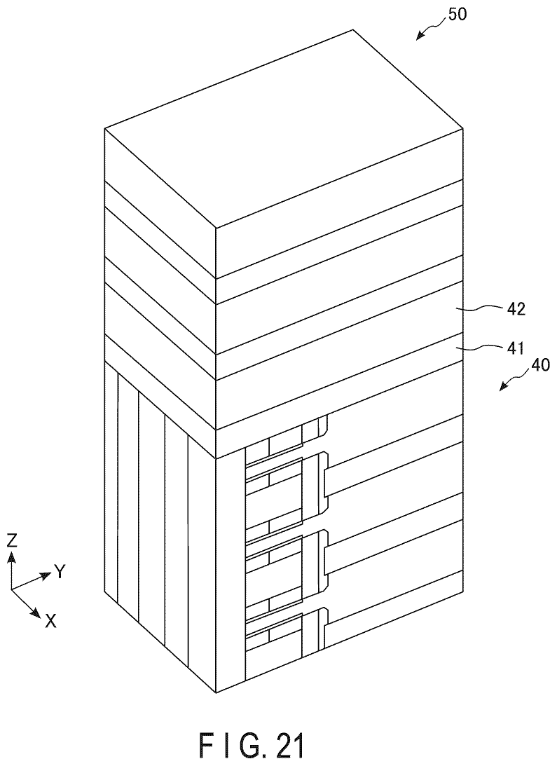

Next, as illustrated in FIG. 21, a mold layer 50 for forming the upper layer array UA is formed on the mold layer 40. Similarly to the mold layer 40, the mold layer 50 includes first sacrificial layers 41 and second sacrificial layers 42 alternately stacked in the Z direction.

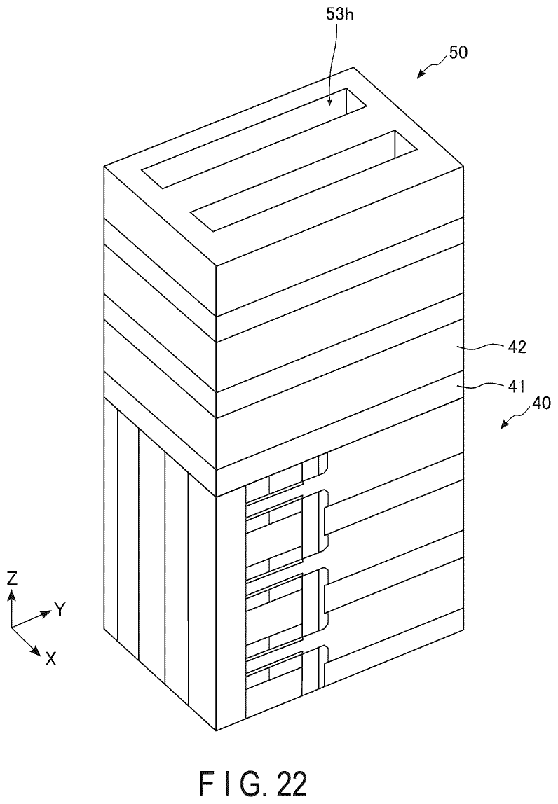

Next, as illustrated in FIG. 22, holes 53h for forming an insulating layer for separating an active area of the cell transistor CT are formed in the mold layer 50.

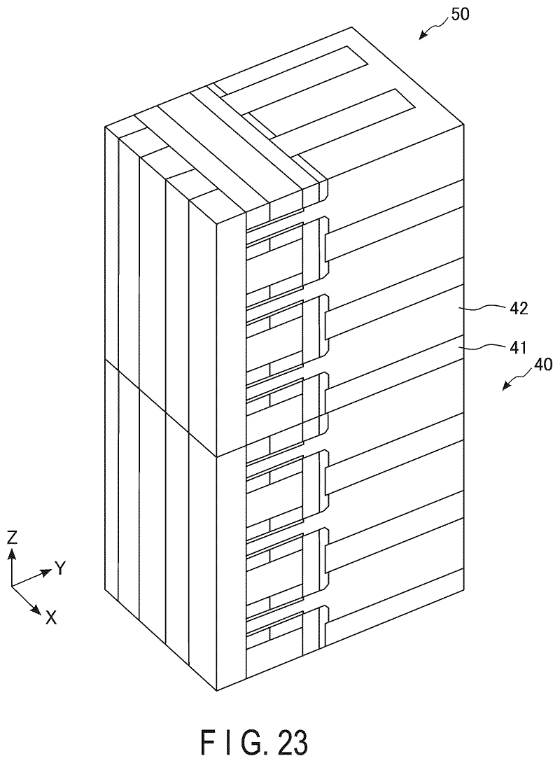

Thereafter, similarly to the mold layer 40, the manufacturing process illustrated in FIGS. 7 to 20 is performed on the mold layer 50 to form a structure similar to the structure illustrated in FIG. 20 as illustrated in FIG. 23.

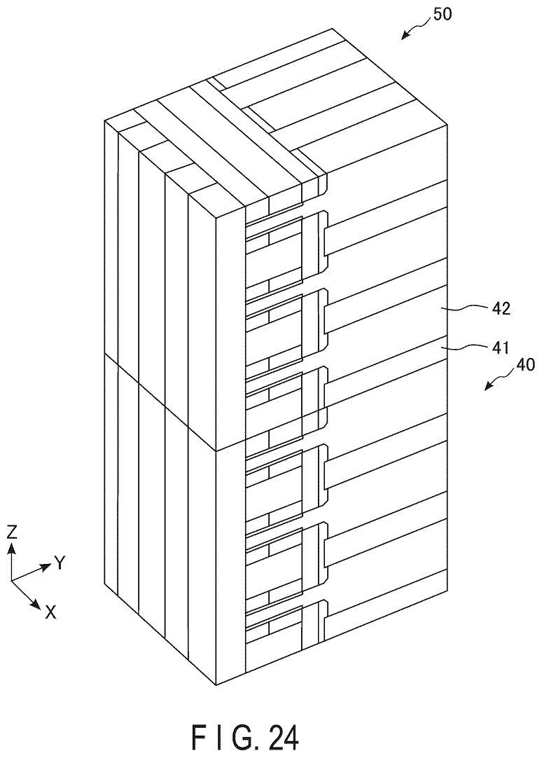

Next, as illustrated in FIG. 24, the first sacrificial layers 41 and the second sacrificial layers 42 at the other end portions of the mold layers 40 and 50 in the positive direction in the Y direction are removed. Hereinafter, in this process, the stacked surface of the first sacrificial layers 41 and the second sacrificial layers 42 from which the other end portion is removed is referred to as a second slit surface.

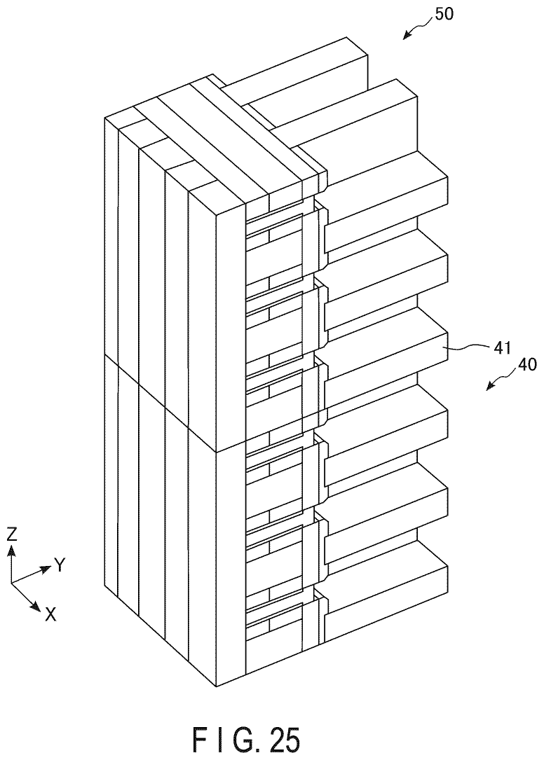

Next, as illustrated in FIG. 25, the second sacrificial layers 42 in the regions where the cell capacitors CC are formed are removed.

Specifically, parts of the second sacrificial layers 42 are removed by etching from the second slit surface, that is, from the other end side of the second sacrificial layers 42 in the positive direction in the Y direction, and the second sacrificial layers 42 are retracted. In this process, the second sacrificial layers 42 are removed up to the front of a region where the cell transistor CT is formed, for example, up to the front of the gate insulating layer 22.

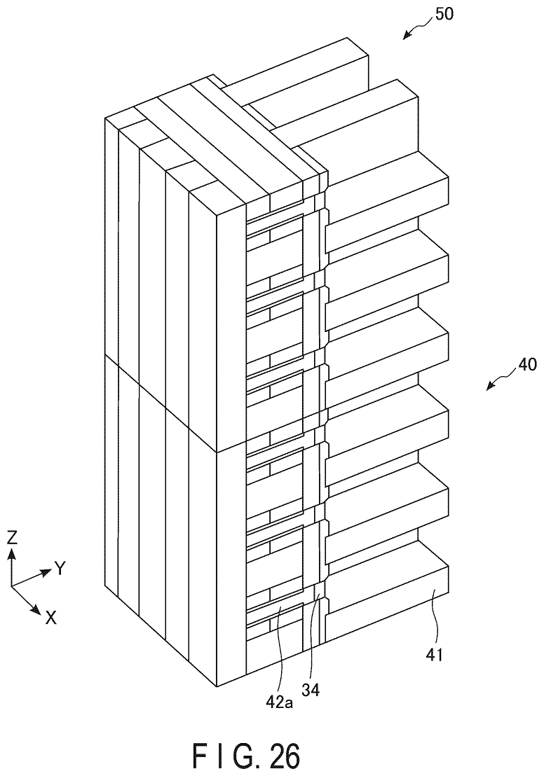

Next, as illustrated in FIG. 26, conductive layers 34 are formed on the other end face of the second sacrificial layers 42 which have been partially removed, that is, the other end face of the beam portions 42a. The conductive layers 34 include, for example, an ITO layer.

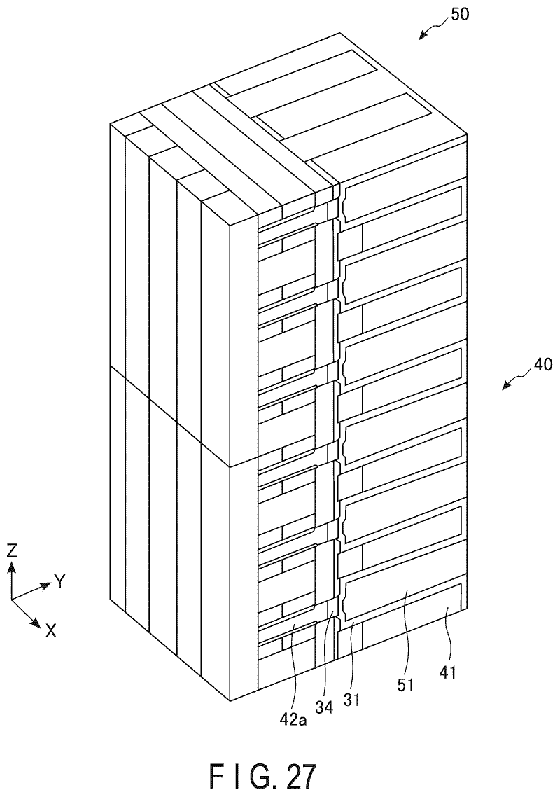

Next, as illustrated in FIG. 27, the first electrode layers 31 of the cell capacitors CC are formed on the conductive layers 34 and the first sacrificial layers 41. Further, sacrificial layers (for example, silicon nitride layers) 51 are formed on the first electrode layers 31. The first electrode layers 31 include, for example, a titanium nitride layer.

Specifically, for example, CVD is used to form the first electrode layers 31 on inner surfaces of spaces created by the removal of the second sacrificial layers 42. Further, the sacrificial layers 51 are embedded on the first electrode layers 31.

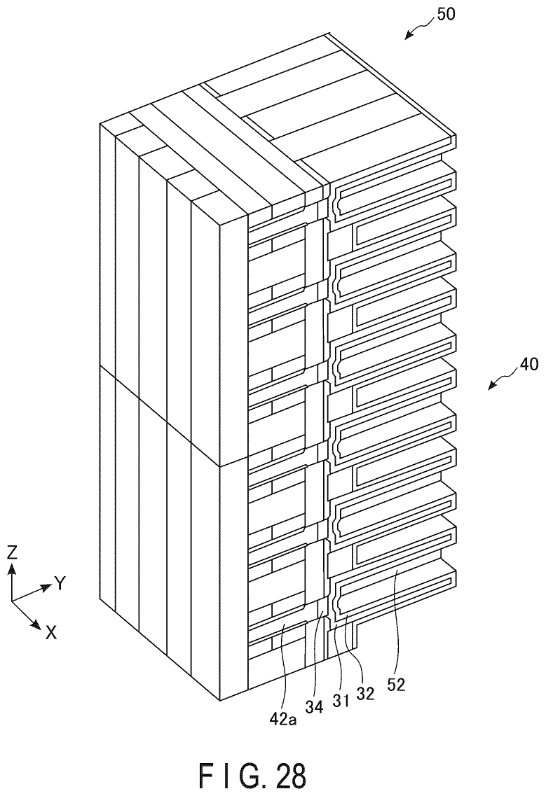

Next, as shown in FIG. 28, insulating layers 32 of the cell capacitors CC are formed on the first electrode layers 31, and high dielectric layers 52 are further formed. The high dielectric layers 52 have a dielectric constant higher than the dielectric constant of the insulating layers 32.

Specifically, the sacrificial layers 51 are removed, and the insulating layers 32 are formed on the first electrode layers 31. Further, the high dielectric layers 52 are formed on the insulating layers 32.

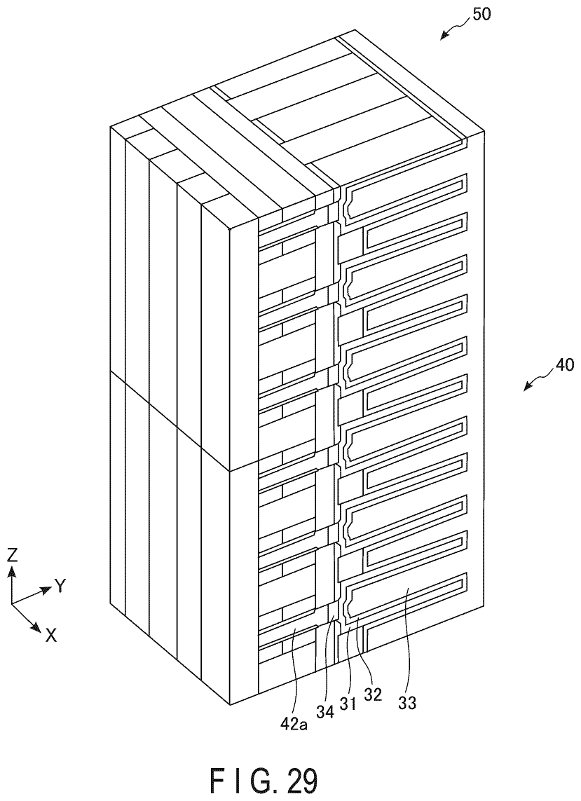

Next, as illustrated in FIG. 29, the second electrode layers 33 of the cell capacitors CC are formed on the insulating layers 32 and the high dielectric layers 52. The second electrode layers 33 include, for example, a titanium nitride layer.

Specifically, the second electrode layers 33 are formed on the insulating layers 32 and the high dielectric layers 52 in such a way as to face the first electrode layers 31.

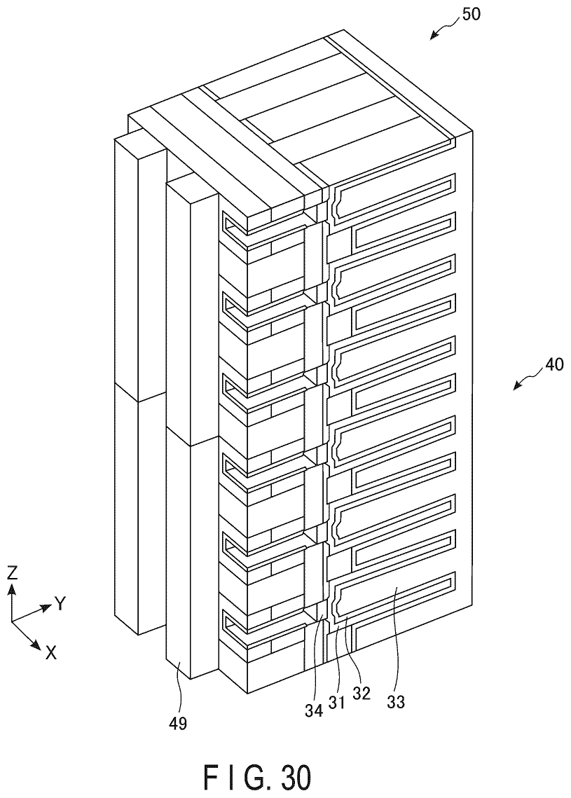

Next, as illustrated in FIG. 30, the sacrificial layers 48a formed in the region where the bit line BL is provided are removed. Further, the beam portions 42a of the second sacrificial layers 42 formed in the regions where the semiconductor layers (alternatively, the channel layers) of the cell transistors CT are provided are removed.

Specifically, the sacrificial layers 48a are removed to expose the surfaces of the beam portions 42a of the second sacrificial layers 42. Subsequently, the beam portions 42a are removed by etching from one end side of the beam portions 42a in the negative direction of the Y direction. As a result, as illustrated in FIG. 30, the beam portions 42a of the second sacrificial layers 42 are removed.

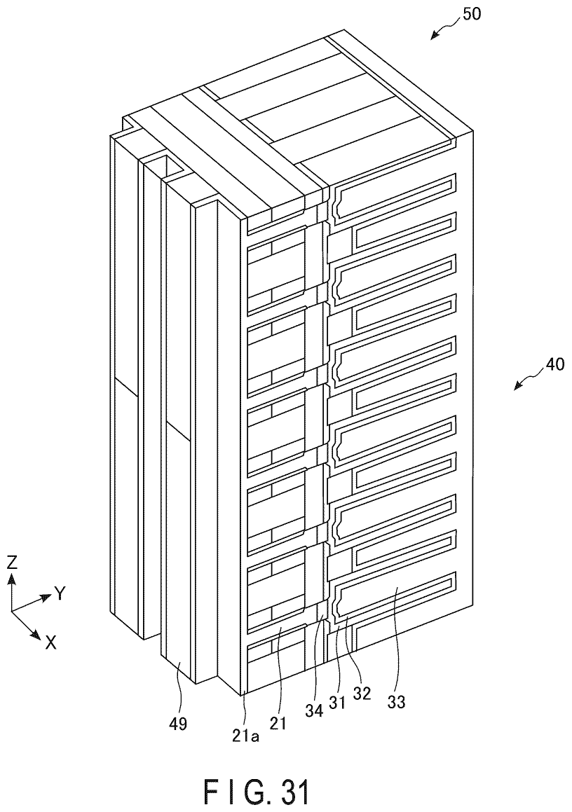

Next, as illustrated in FIG. 31, the semiconductor layer 21 is formed in a region where the semiconductor layer of the cell transistors CT is provided. At the same time, the conductive layer 21a is formed in a region where the bit line BL is provided. The semiconductor layer 21 and the conductive layer 21a contain, for example, a conductive oxide (alternatively, a semiconductor material layer). The conductive oxide contains, for example, In, Ga, Zn, and O.

Specifically, the semiconductor layer 21 is formed in a region where the semiconductor layer of the cell transistor CT from which the beam portions 42a of the second sacrificial layers 42 are removed is provided. Together with the formation of the semiconductor layer 21, the conductive layer 21a extending in the Z direction is formed in such a way as to be connected to the semiconductor layer 21. That is, the sacrificial layer 48a and the beam portion 42a are replaced with the semiconductor layer 21 and the conductive layer 21a. Here, the sacrificial layer 48a is not completely replaced with the semiconductor layer 21 and the conductive layer 21a, and a gap in which the bit line BL is provided remains. Note that the conductive layer 21a may be formed separately from the semiconductor layer 21.

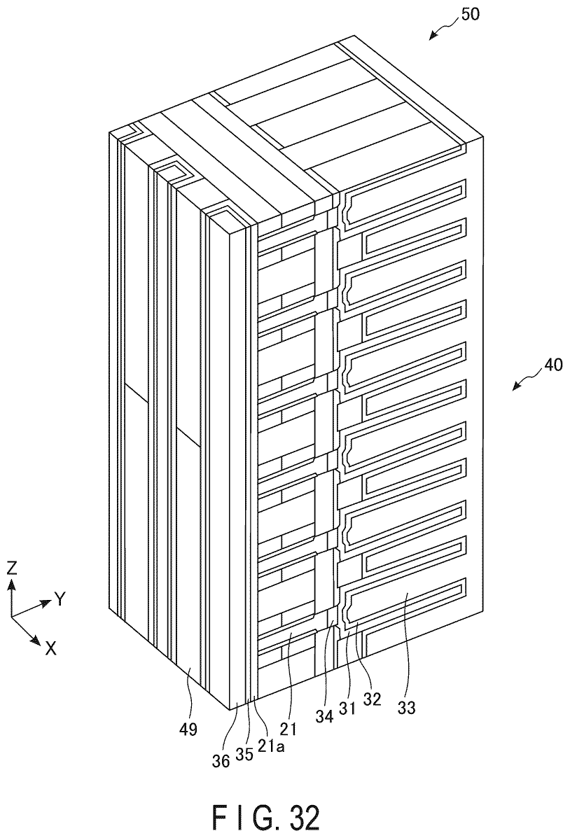

Next, as illustrated in FIG. 32, conductive layers 35 and 36 are formed in a region where the bit line BL is provided.

Specifically, the conductive layers 35 and 36 extending in the Z direction are sequentially formed on the side surface of the conductive layer 21a. The conductive layers 21a, 35, and 36 function as the bit line BL. As described above, the manufacturing of the memory cell array 11 of the embodiment ends.

### 3. Modification 1

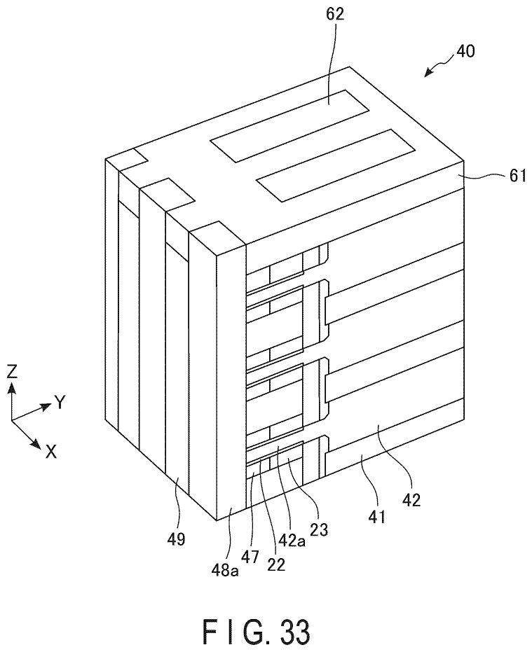

Hereinafter, a method of manufacturing the memory cell array 11 in the memory device 1 of Modification 1 of the embodiment will be described. FIGS. 33 to 35 are perspective views illustrating a method of manufacturing the memory cell array 11 in the memory device of Modification 1 of the embodiment.

As illustrated in FIG. 33, an insulating layer (for example, a silicon oxide layer) 61 and insulating layers 62 for separating an active area of the cell transistor CT are formed on the mold layer 40 illustrated in FIG. 20.

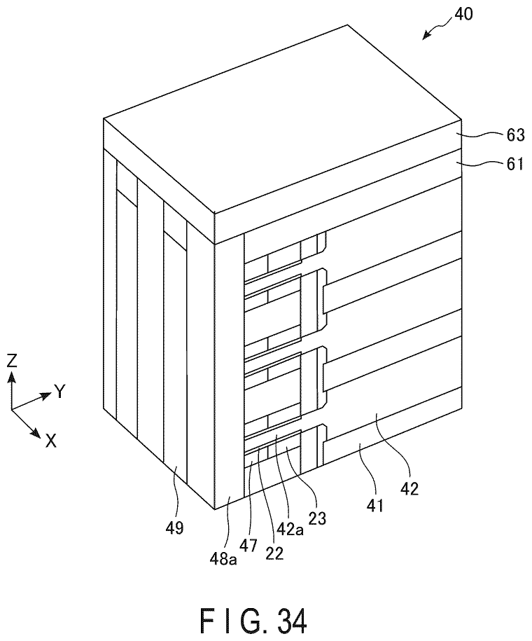

Next, as illustrated in FIG. 34, an insulating layer 63 is formed on the insulating layer 61. The insulating layer 63 serves as an etching stop layer for stopping etching in an etching process of a layer formed above the layer. The etching stop layer contains metal oxide, metal nitride, or metal. The etching stop layer includes, for example, aluminum oxide, titanium nitride, tungsten, or a stack of titanium nitride and tungsten.

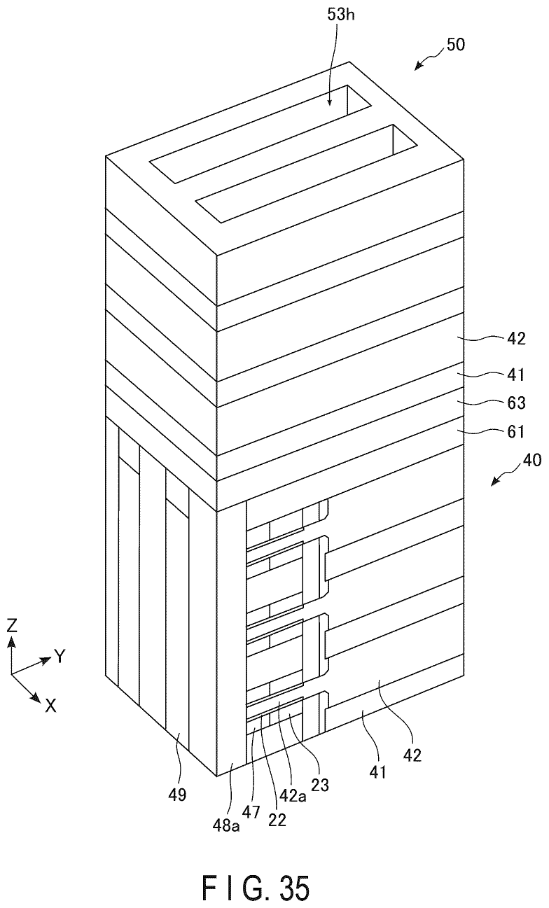

Thereafter, as illustrated in FIG. 35, a mold layer 50 in which first sacrificial layers (for example, silicon nitride layers) 41 and second sacrificial layers (for example, polycrystalline silicon layers) 42 are alternately stacked in the Z direction is formed. Further, holes 53h for forming an insulating layer for separating an active area of the cell transistor CT are formed in the mold layer 50. Subsequent processes are similar to the manufacturing processes described in FIGS. 7 to 32.

### 4. Modification 2

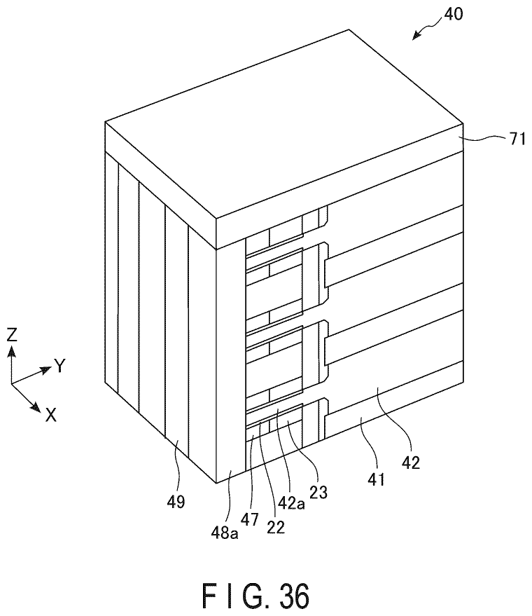

Hereinafter, a method of manufacturing a memory cell array 11 in a memory device 1 of Modification 2 of the embodiment will be described. FIGS. 36 to 38 are perspective views illustrating a method of manufacturing the memory cell array 11 in the memory device of Modification 2 of the embodiment.

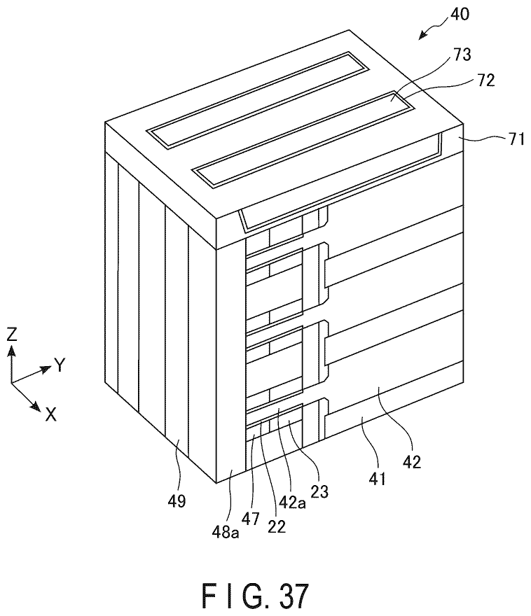

As illustrated in FIG. 36, an insulating layer (for example, a silicon oxide layer) 71 is formed on the mold layer 40 illustrated in FIG. 20. Subsequently, as illustrated in FIG. 37, barrier layers (for example, titanium nitride) 72 and metal layers (for example, tungsten) 73 are formed in the insulating layer 71. The metal layers 73 serve as etching stop layers for stopping etching in an etching process of a layer formed above this layer.

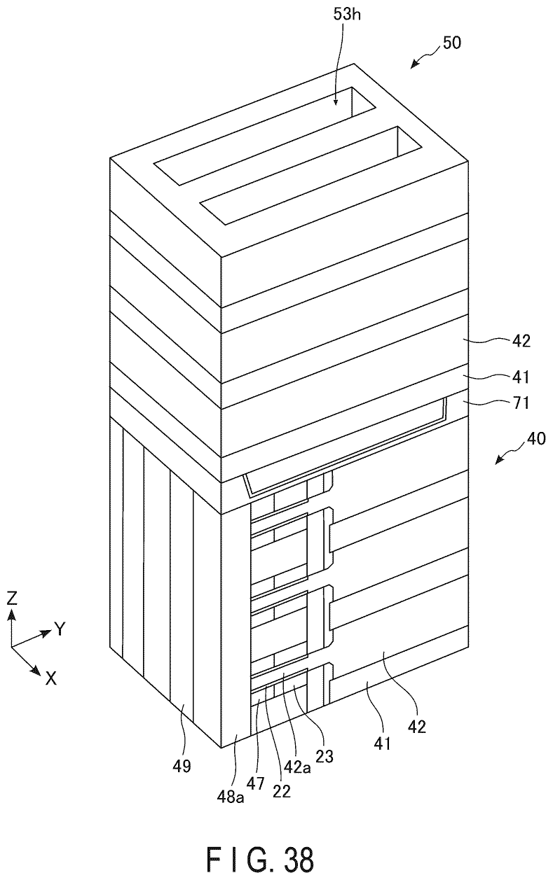

Thereafter, as illustrated in FIG. 38, a mold layer 50 in which first sacrificial layers (for example, silicon nitride layers) 41 and second sacrificial layers (for example, polycrystalline silicon layers) 42 are alternately stacked in the Z direction is formed. Further, holes 53h for forming an insulating layer for separating an active area of the cell transistor CT are formed in the mold layer 50. Subsequent processes are similar to the manufacturing processes described in FIGS. 7 to 32.

### 5. Modification 3

Hereinafter, as Modification 3 of the embodiment, another method of manufacturing the memory cell array 11 will be described. In the embodiment, silicon nitride layers are used as the first sacrificial layers 41, amorphous or polycrystalline silicon layers are used as the second sacrificial layers 42, a stacked structure in which the first sacrificial layers 41 and the second sacrificial layers 42 are alternately stacked is formed, and the cell transistors CT and the cell capacitors CC as the memory cells MC are formed. However, it is also possible to form the memory cell MC using other layers as the first sacrificial layers and the second sacrificial layers.

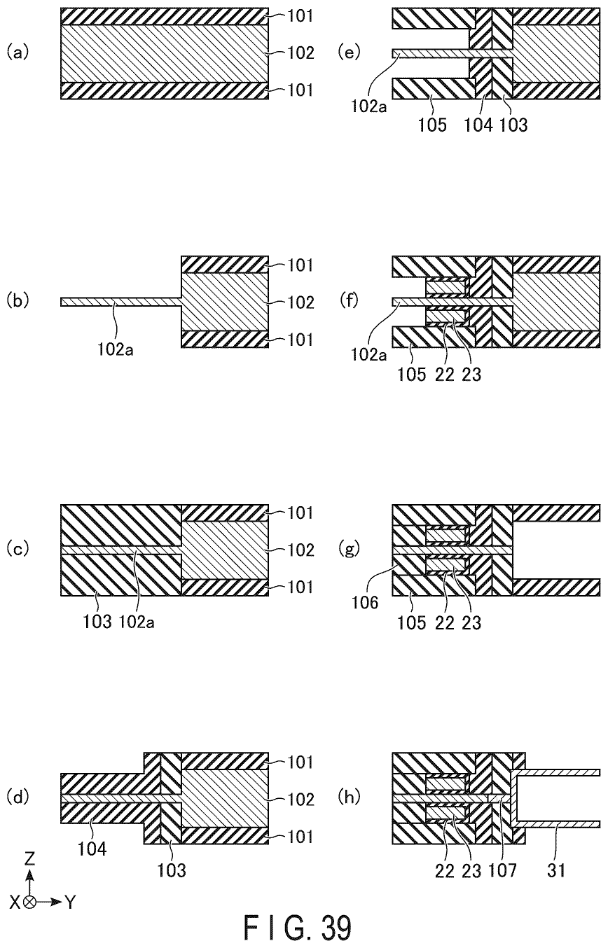

FIGS. 39 to 44 are cross-sectional views each illustrating a method of manufacturing the memory cell array 11 in the memory device of Modification 3 of the embodiment. FIGS. 39 to 44 schematically illustrate processes of forming the cell transistor CT and the cell capacitor CC included in the memory cell MC.

(1) A case where a stacked structure of amorphous or polycrystalline silicon layer/silicon nitride layer/amorphous or polycrystalline silicon layer/silicon nitride layer (hereinafter, also referred to as a SNSN stacked structure) is used (the same as the structure described in the embodiment).

First, as shown in FIG. 39(a), silicon nitride layers 101 and an amorphous or polycrystalline silicon layer 102 are alternately stacked.

Next, the silicon nitride layers 101 are retracted by etching to expose the amorphous or polycrystalline silicon layer 102. As shown in FIG. 39(b), the exposed amorphous or polycrystalline silicon layer 102 is trimmed to form a beam portion 102a of the amorphous or polycrystalline silicon layer 102.

As illustrated in FIG. 39(c), a silicon oxide layer 103 is formed on the upper surface and the lower surface of the beam portion 102a of the amorphous or polycrystalline silicon layer 102.

Next, the silicon oxide layer 103 is retracted by etching to expose the beam portion 102a of the amorphous or polycrystalline silicon layer 102. As illustrated in FIG. 39(d), a silicon nitride layer 104 is formed on the upper surface and the lower surface of the beam portion 102a of the amorphous or polycrystalline silicon layer 102.

Next, a silicon oxide layer 106 is formed on a silicon nitride layer 105. As illustrated in FIG. 39(e), the silicon nitride layer 105 between the beam portion 102a of the amorphous or polycrystalline silicon layer 102 and the silicon oxide layer 106 is retracted by etching.

As illustrated in FIG. 39(f), a gate insulating layer 22 is formed on the upper surface and the lower surface of the beam portion 102a of the amorphous or polycrystalline silicon layer 102. A gate electrode layer 23 is formed on the gate insulating layer 22.

As shown in FIG. 39(g), a silicon oxide layer 106 is formed on the surface of the gate electrode layer 23 in the negative direction of the Y direction. The amorphous or polycrystalline silicon layer 102 excluding the beam portion 102a is removed by etching.

As illustrated in FIG. 39(h), the beam portion 102a in the positive direction of the Y direction is retracted by etching. That is, the beam portion 102a on a side where the cell capacitor CC is formed is retracted by etching. An ITO layer 107 is formed in a region of the retreated beam portion 102a. A first electrode layer (alternatively, the cylinder layer) 31 of the cell capacitor CC is formed on the ITO layer 107.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted.

(2) The case of using a stacked structure of silicon oxide layer/amorphous or polycrystalline silicon layer/silicon oxide layer/amorphous or polycrystalline silicon layer (hereinafter, also referred to as an OSOS stacked structure).

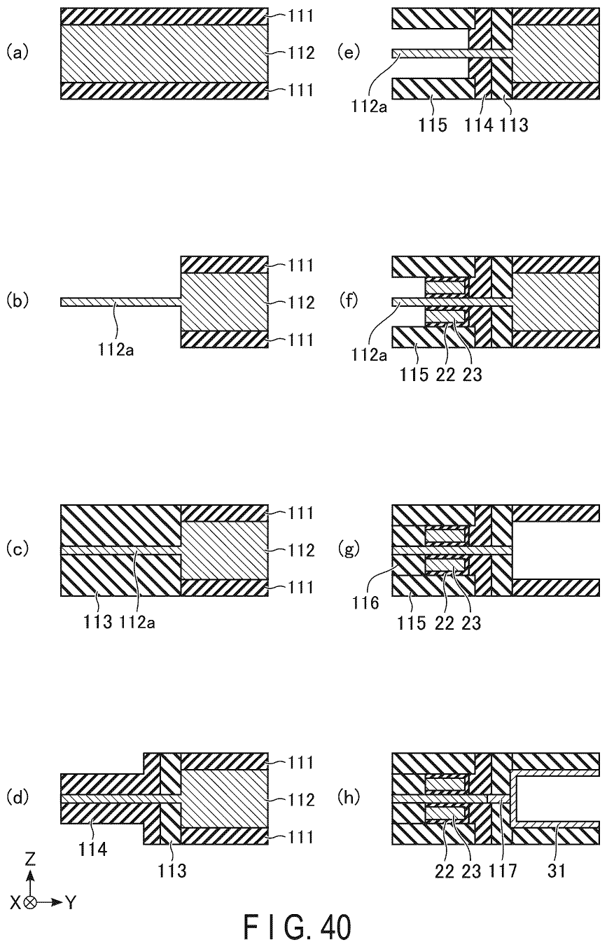

First, as shown in FIG. 40(a), silicon oxide layers 111 and an amorphous or polycrystalline silicon layer 112 are alternately stacked.

Next, the silicon oxide layer 111 is retracted by etching to expose the amorphous or polycrystalline silicon layer 112. As shown in FIG. 40(b), the exposed amorphous or polycrystalline silicon layer 112 is trimmed to form a beam portion 112a of the amorphous or polycrystalline silicon layer 112.

As illustrated in FIG. 40(c), a silicon oxide layer 113 is formed on the upper surface and the lower surface of the beam portion 112a of the amorphous or polycrystalline silicon layer 112.

Next, the silicon oxide layer 113 is retracted by etching to expose the beam portion 112a of the amorphous or polycrystalline silicon layer 112. As illustrated in FIG. 40(d), a silicon nitride layer 114 is formed on the upper surface and the lower surface of the beam portion 112a of the amorphous or polycrystalline silicon layer 112.

Next, a silicon oxide layer 115 is formed on the silicon nitride layer 114. As illustrated in FIG. 40(e), the silicon nitride layer 114 between the beam portion 112a of the amorphous or polycrystalline silicon layer 112 and the silicon oxide layer 115 is retracted by etching.

As illustrated in FIG. 40(f), a gate insulating layer 22 is formed on the upper surface and the lower surface of the beam portion 112a of the amorphous or polycrystalline silicon layer 112. A gate electrode layer 23 is formed on the gate insulating layer 22.

As shown in FIG. 40(g), a silicon oxide layer 116 is formed on the surface of the gate electrode layer 23 in the negative direction of the Y direction. The amorphous or polycrystalline silicon layer 112 excluding the beam portion 112a is removed by etching.

As illustrated in FIG. 40(h), the beam portion 112a in the positive direction of the Y direction is retracted by etching. That is, the beam portion 112a on the side where the cell capacitor CC is formed is retracted by etching. An ITO layer 117 is formed in a region of the retreated beam portion 112a. A first electrode layer 31 of the cell capacitor CC is formed on the ITO layer 117.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted.

(3) A case of using a stacked structure of silicon oxide layer/silicon nitride layer/silicon oxide layer/silicon nitride layer (hereinafter, also referred to as an ONON stacked structure).

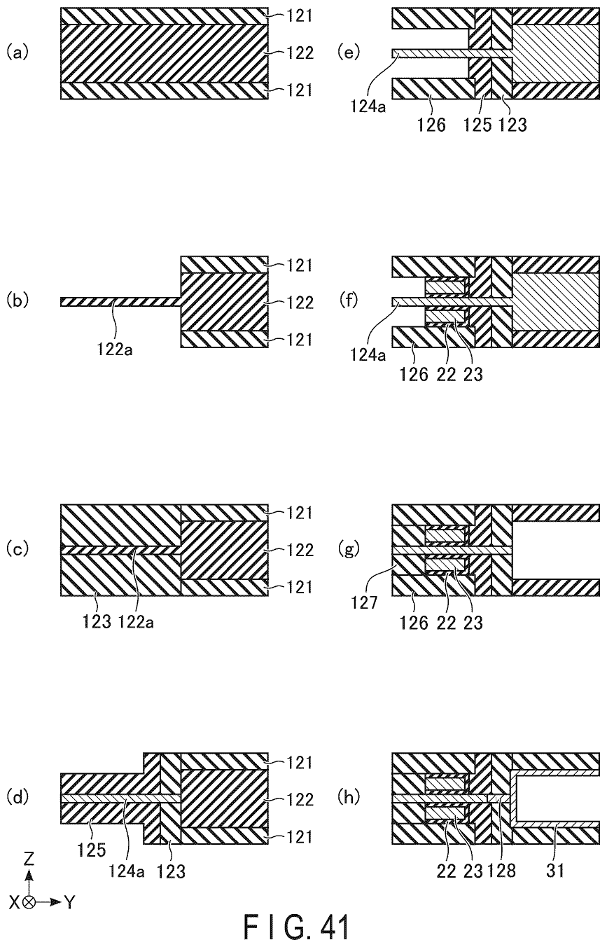

First, as illustrated in FIG. 41(a), silicon oxide layers 121 and a silicon nitride layer 122 are alternately stacked.

Next, the silicon oxide layers 121 are retracted by etching to expose the silicon nitride layer 122. As illustrated in FIG. 41(b), the exposed silicon nitride layer 122 is trimmed to form a beam portion 122a of the silicon nitride layer 122.

As illustrated in FIG. 41(c), a silicon oxide layer 123 is formed on the upper surface and the lower surface of the beam portion 122a of the silicon nitride layer 122.

As illustrated in FIG. 41(d), the beam portion 122a of the silicon nitride layer 122 is replaced with a beam portion 124a of the amorphous or polycrystalline silicon layer. That is, the beam portion 122a of the silicon nitride layer 122 is removed by etching, and the beam portion 124a of the amorphous or polycrystalline silicon layer is formed in a region where the beam portion 122a is removed. Thereafter, the silicon oxide layer 123 is retracted by etching to expose the beam portion 124a of the amorphous or polycrystalline silicon layer. A silicon nitride layer 125 is formed on the upper surface and the lower surface of the beam portion 124a of the amorphous or polycrystalline silicon layer.

Next, a silicon oxide layer 126 is formed on the silicon nitride layer 125. As illustrated in FIG. 41(e), the silicon nitride layer 125 between the beam portion 124a of the amorphous or polycrystalline silicon layer and the silicon oxide layer 126 is retracted by etching.

As illustrated in FIG. 41(f), a gate insulating layer 22 is formed on the upper surface and the lower surface of the beam portion 124a of the amorphous or polycrystalline silicon layer. A gate electrode layer 23 is formed on the gate insulating layer 22.

As shown in FIG. 41(g), a silicon oxide layer 127 is formed on the surface of the gate electrode layer 23 in the negative direction of the Y direction. Further, the silicon nitride layer 122 is removed by etching.

As illustrated in FIG. 41(h), a beam portion 124a in the positive direction of the Y direction is retracted by etching. That is, the beam portion 124a on the side where the cell capacitor CC is formed is retracted by etching. An ITO layer 128 is formed in a region of the retreated beam portion 124a. A first electrode layer 31 of the cell capacitor CC is formed on the ITO layer 128.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted.

(4) The case of using a stacked structure of silicon oxide layer/silicon nitride layer/amorphous or polycrystalline silicon layer/silicon nitride layer (hereinafter, also referred to as an ONSN stacked structure).

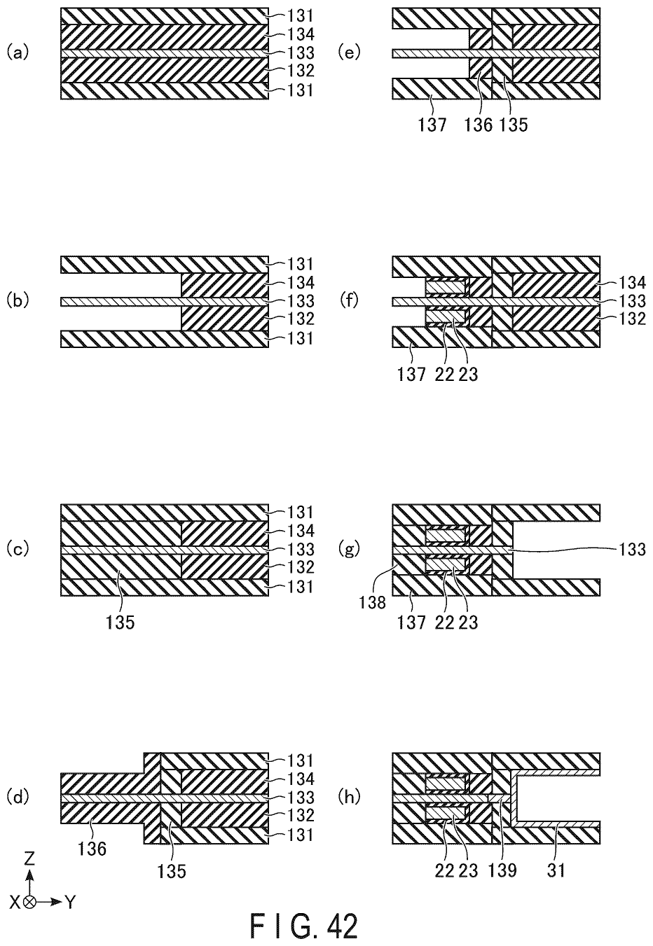

First, as illustrated in FIG. 42(a), a silicon oxide layer 131, a silicon nitride layer 132, an amorphous or polycrystalline silicon layer 133, and a silicon nitride layer 134 are sequentially stacked.

As illustrated in FIG. 42(b), the silicon nitride layers 132 and 134 are retracted by etching to expose the amorphous or polycrystalline silicon layer 133.

As illustrated in FIG. 42(c), a silicon oxide layer 135 is formed on the upper surface and the lower surface of the exposed amorphous or polycrystalline silicon layer 133.

As illustrated in FIG. 42(d), the silicon oxide layers 131 and 135 are retracted by etching to expose the amorphous or polycrystalline silicon layer 133. A silicon nitride layer 136 is formed on the upper surface and the lower surface of the amorphous or polycrystalline silicon layer 133.

Next, a silicon oxide layer 137 is formed on the silicon nitride layer 136. As illustrated in FIG. 42(e), the silicon nitride layer 136 between the amorphous or polycrystalline silicon layer 133 and the silicon oxide layer 137 is retracted by etching.

As illustrated in FIG. 42(f), a gate insulating layer 22 is formed on the upper surface and the lower surface of the amorphous or polycrystalline silicon layer 133. A gate electrode layer 23 is formed on the gate insulating layer 22.

As shown in FIG. 42(g), a silicon oxide layer 138 is formed on the surface of the gate electrode layer 23 in the negative direction of the Y direction. The silicon nitride layers 132 and 134 in the positive direction of the Y direction are removed by etching. Further, the amorphous or polycrystalline silicon layer 133 in the positive direction of the Y direction is retracted by etching.

As illustrated in FIG. 42(h), the amorphous or polycrystalline silicon layer 133 in the positive direction of the Y direction is further retracted by etching. That is, the amorphous or polycrystalline silicon layer 133 on the side where the cell capacitor CC is formed is retracted by etching. An ITO layer 139 is formed in a region of the retreated amorphous or polycrystalline silicon layer 133. A first electrode layer 31 of the cell capacitor CC is formed on the ITO layer 139.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted.

(5) A case of using a stacked structure of silicon oxycarbide layer/silicon oxide layer/amorphous or polycrystalline silicon layer/silicon nitride layer (hereinafter, also referred to as an NSOC stacked structure).

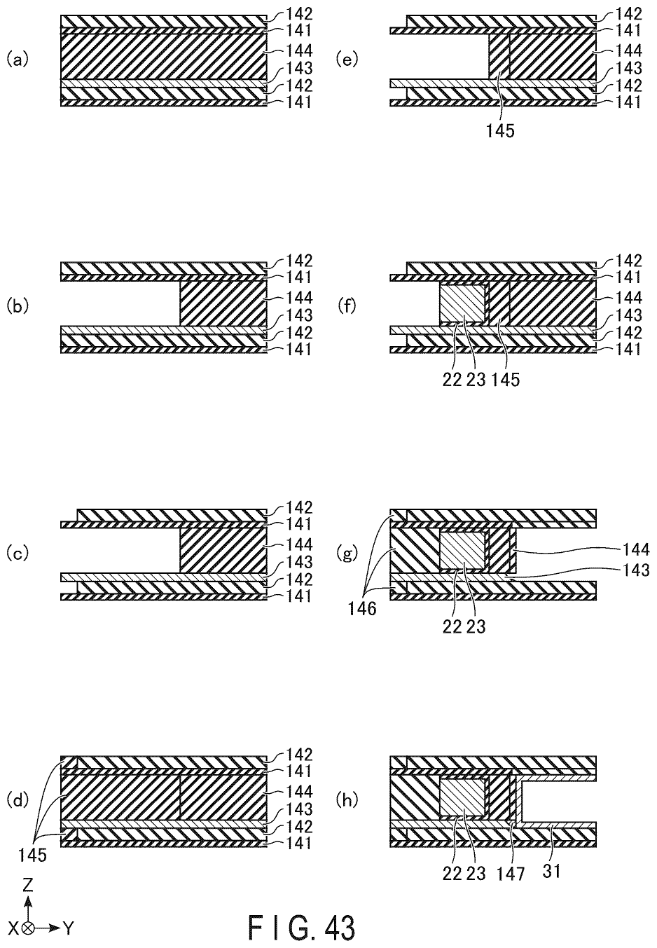

First, as illustrated in FIG. 43(a), a silicon oxycarbide (SiOC) layer 141, a silicon oxide layer 142, an amorphous or polycrystalline silicon layer 143, and a silicon nitride layer 144 are sequentially stacked.

As illustrated in FIG. 43(b), the silicon nitride layer 144 is retracted by etching to expose the amorphous or polycrystalline silicon layer 143.

As illustrated in FIG. 43(c), the silicon oxide layer 142 is trimmed.

As illustrated in FIG. 43(d), a silicon nitride layer 145 is formed on the structure illustrated in FIG. 43(c).

As illustrated in FIG. 43(e), the silicon nitride layer 145 is retracted by etching to expose the amorphous or polycrystalline silicon layer 143.

As illustrated in FIG. 43(f), a gate insulating layer 22 is formed on the upper surface of the amorphous or polycrystalline silicon layer 143. A gate electrode layer 23 is formed on the gate insulating layer 22.

As shown in FIG. 43(g), a silicon oxide layer 146 is formed on the surface of the gate electrode layer 23 in the negative direction of the Y direction. Subsequently, the silicon nitride layer 144 in the positive direction in the Y direction is retracted by etching. Further, the amorphous or polycrystalline silicon layer 143 in the positive direction of the Y direction is retracted by etching. That is, the silicon nitride layer 144 and the amorphous or polycrystalline silicon layer 143 on the side where the cell capacitor CC is formed are retracted by etching.

As shown in FIG. 43(h), an ITO layer 147 is formed in the region of the retreated amorphous or polycrystalline silicon layer 143. A first electrode layer 31 of the cell capacitor CC is formed on the ITO layer 147.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted. A method for manufacturing a memory cell using the above-described NSOC stacked structure will be described in detail later.

(6) A case of using a stacked structure of silicon oxide layer/polycrystalline silicon layer/silicon nitride layer/polycrystalline silicon layer (hereinafter, also referred to as an OPNP stacked structure).

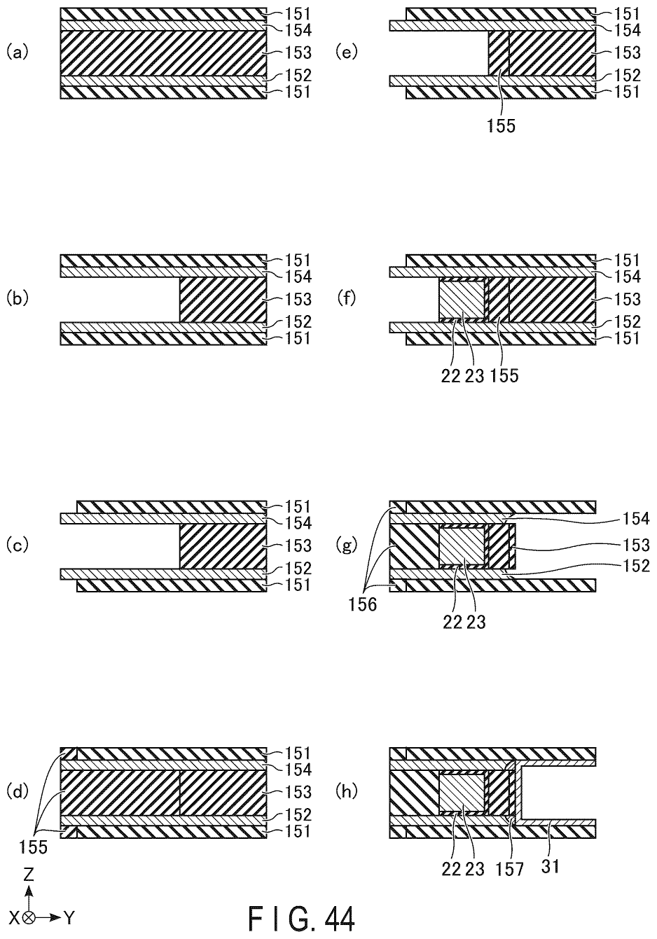

First, as illustrated in FIG. 44(a), a silicon oxide layer 151, a polycrystalline silicon layer 152, a silicon nitride layer 153, and a polycrystalline silicon layer 154 are sequentially stacked.

As illustrated in FIG. 44(b), the silicon nitride layer 153 is retracted by etching to expose the polycrystalline silicon layers 152 and 154.

As illustrated in FIG. 44(c), the silicon oxide layer 151 is trimmed.

As illustrated in FIG. 44(d), a silicon nitride layer 155 is formed on the structure illustrated in FIG. 44(c).

As illustrated in FIG. 44(e), the silicon nitride layer 155 is retracted by etching to expose the polycrystalline silicon layers 152 and 154.

As illustrated in FIG. 44(f), a gate insulating layer 22 is formed on the upper surface of the polycrystalline silicon layer 152 and the lower surface of the polycrystalline silicon layer 154. A gate electrode layer 23 is formed on the gate insulating layer 22.

As shown in FIG. 44(g), a silicon oxide layer 156 is formed on the surface of the gate electrode layer 23 in the negative direction of the Y direction. The silicon nitride layer 153 in the positive direction of the Y direction is retracted by etching. Further, the polycrystalline silicon layers 152 and 154 in the positive direction of the Y direction are retracted by etching. That is, the silicon nitride layer 153 and the polycrystalline silicon layers 152 and 154 on the side where the cell capacitor CC is formed are retracted by etching.

As illustrated in FIG. 44(h), an ITO layer 157 is formed in regions of the retreated polycrystalline silicon layers 152 and 154. A first electrode layer 31 of the cell capacitor CC is formed on the ITO layer 157.

Thereafter, although not illustrated, an insulating layer (alternatively, the dielectric layer) 32 is formed on the first electrode layer 31. Further, a second electrode layer 33 of the cell capacitor CC is formed on the insulating layer 32. The description of the subsequent processes is omitted.

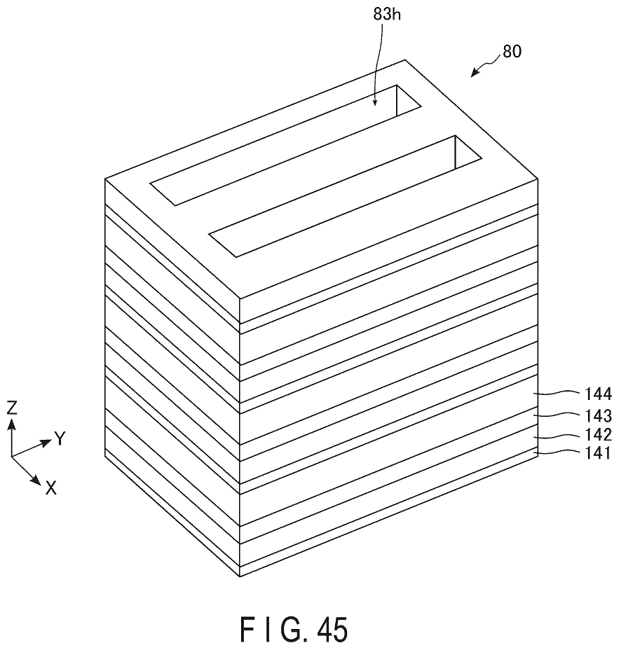

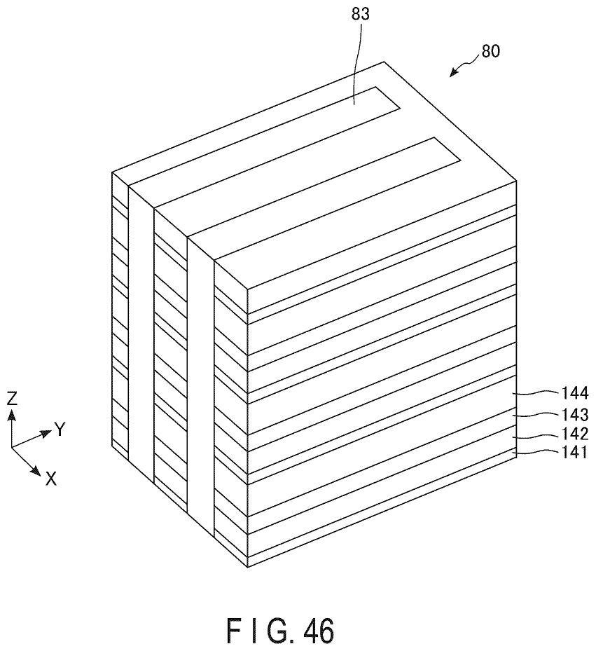

Hereinafter, a method of manufacturing a memory cell using the NSOC stacked structure of the above item (5) will be described with reference to perspective views illustrated in FIGS. 45 to 48. FIGS. 45 to 48 are perspective views illustrating a method of manufacturing a memory cell array using the NSOC stacked structure in Modification 3.

First, as illustrated in FIG. 45, a mold layer 80 in which a silicon oxycarbide layer 141, a silicon oxide layer 142, an amorphous or polycrystalline silicon layer 143, and a silicon nitride layer 144 are sequentially stacked in the Z direction is formed. Further, holes 83h for forming an insulating layer for separating an active area of the cell transistor CT are formed in the mold layer 80.

Next, as illustrated in FIG. 46, silicon oxide layers 83 are formed in the holes 83h formed in the mold layer 80 by using, for example, CVD. Furthermore, one end portion of the mold layer 80 in the negative direction of the Y direction is removed. Hereinafter, in this process, a stacked surface of the mold layer 80 from which one end portion is removed is referred to as a slit surface.

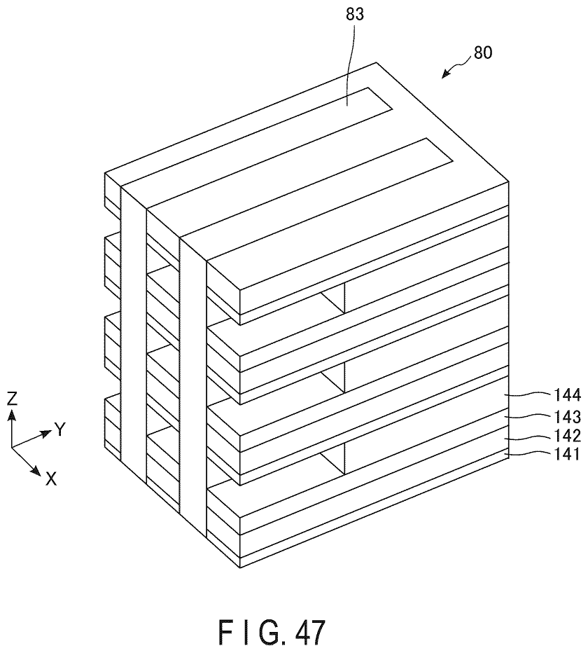

Next, as illustrated in FIG. 47, a part of the silicon nitride layer 144 is removed from the slit surface. That is, a part of the silicon nitride layer 144 is removed by etching from one end side of the silicon nitride layer 144 in the negative direction in the Y direction, and the silicon nitride layer 144 is retracted.

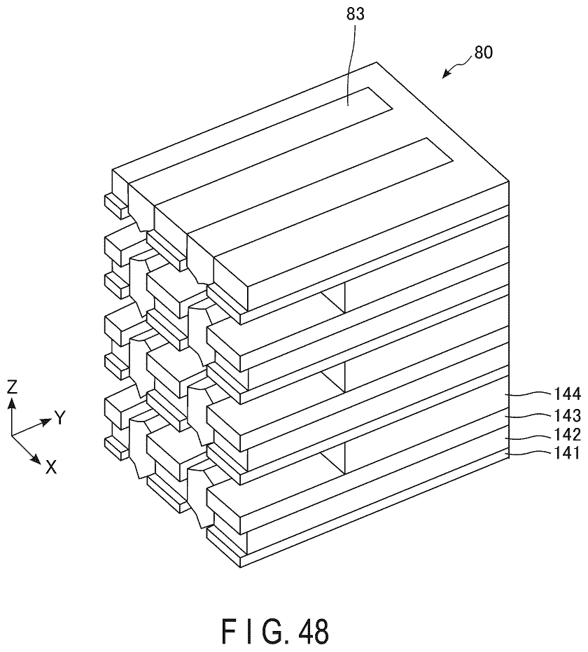

Next, as illustrated in FIG. 48, the silicon oxide layer 83 is trimmed to form a region where the word line WL is arranged. That is, the silicon oxide layer 83 is removed from a region from which the silicon nitride layer 144 has been removed by etching to form a space for arranging the word line WL.

Thereafter, although not illustrated, a gate insulating layer 22 is formed on the upper surface of the amorphous or polycrystalline silicon layer 143. Further, the word line WL as the gate electrode layer 23 is formed on the gate insulating layer 22. The description of the subsequent processes is omitted.

### 6. Bit Line Selection Transistor

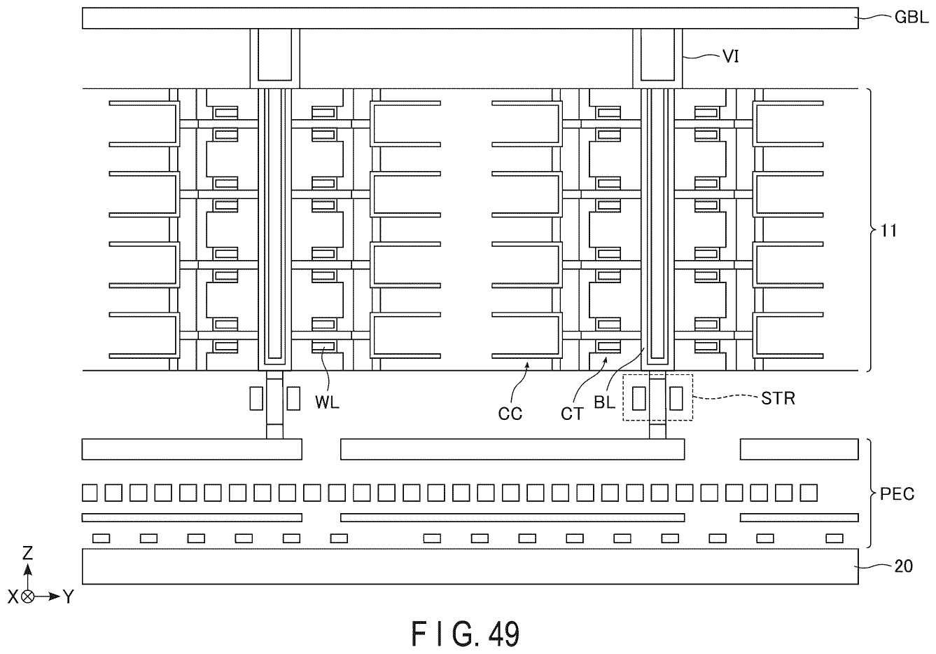

Next, the layout of the bit line selection transistor used in the memory device of the embodiment will be described with reference to FIGS. 49, 50, and 51. FIGS. 49, 50, and 51 are cross-sectional views illustrating a first example, a second example, and a third example of the layout of the bit line selection transistor, respectively. In FIGS. 49, 50, and 51, the description of a filling, an interlayer insulating layer, and the like in the cross section of the layer is omitted.

FIG. 49 is a cross-sectional view illustrating a first example of the layout of the bit line selection transistor in the memory device of the embodiment.

A peripheral circuit PEC is provided below the memory cell array 11 (that is, the negative direction in the Z direction). The peripheral circuit PEC includes, for example, a CMOS circuit. A bit line selection transistor STR for selecting the bit line BL is provided between the memory cell array 11 and the peripheral circuit PEC.

In addition, a global bit line GBL is provided above the memory cell array 11 (that is, the positive direction in the Z direction). A plurality of bit lines BL in the memory cell array 11 is connected to the global bit line GBL via a contact plug VI.

In other words, the peripheral circuit PEC is arranged on the semiconductor substrate 20. The bit line selection transistor STR is disposed above the peripheral circuit PEC. The memory cell array 11 is disposed above the bit line selection transistor STR. Further, a global bit line GBL is arranged above the memory cell array 11.

As described above, the memory cell array 11 includes a plurality of memory cells MC. Each of the memory cells MC includes a cell transistor CT and a cell capacitor CC. One end of the cell transistor CT is connected to the cell capacitor CC. The other end of the cell transistor CT is connected to the bit line BL. One end of the bit line BL is connected to the peripheral circuit PEC via the bit line selection transistor STR. The other end of the bit line BL is connected to the global bit line GBL via the contact plug VI.

The bit line selection transistor STR includes, for example, single crystal or polycrystalline silicon or a conductive oxide as a semiconductor layer (alternatively, a channel layer).

The peripheral circuit PEC includes, for example, a sense amplifier 19, a column selector 16, a write circuit 17, a read circuit 18, a row selector 15, a voltage generator 14, a control circuit 13, and an input/output circuit 12.

As described above, in a case where the bit line selection transistor STR is arranged between the peripheral circuit PEC arranged in the Z direction and the memory cell array 11, it is possible to reduce the region on the XY plane necessary for forming the bit line selection transistor STR.

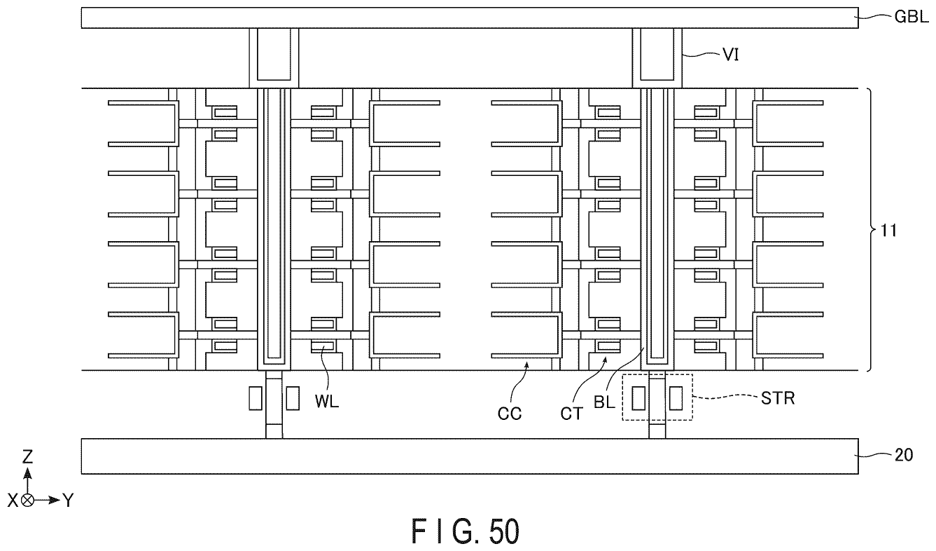

FIG. 50 is a cross-sectional view illustrating a second example of the layout of the bit line selection transistor in the memory device of the embodiment.

A bit line selection transistor STR is provided above the semiconductor substrate 20 (that is, the positive direction in the Z direction). A memory cell array 11 is provided above the bit line selection transistor STR. That is, the bit line selection transistor STR is provided between the semiconductor substrate 20 and the memory cell array 11.

In addition, a global bit line GBL is provided above the memory cell array 11. A plurality of bit lines BL in the memory cell array 11 is connected to the global bit line GBL via a contact plug VI.

One end of the cell transistor CT is connected to the cell capacitor CC. The other end of the cell transistor CT is connected to the bit line BL. One end of the bit line BL is connected to the semiconductor substrate 20 via the bit line selection transistor STR. The other end of the bit line BL is connected to the global bit line GBL via the contact plug VI.

As described above, in a case where the bit line selection transistors STR are arranged between the semiconductor substrate 20 and the memory cell array 11 arranged in the Z direction, it is possible to reduce a region on the XY plane necessary for forming the bit line selection transistors STR.

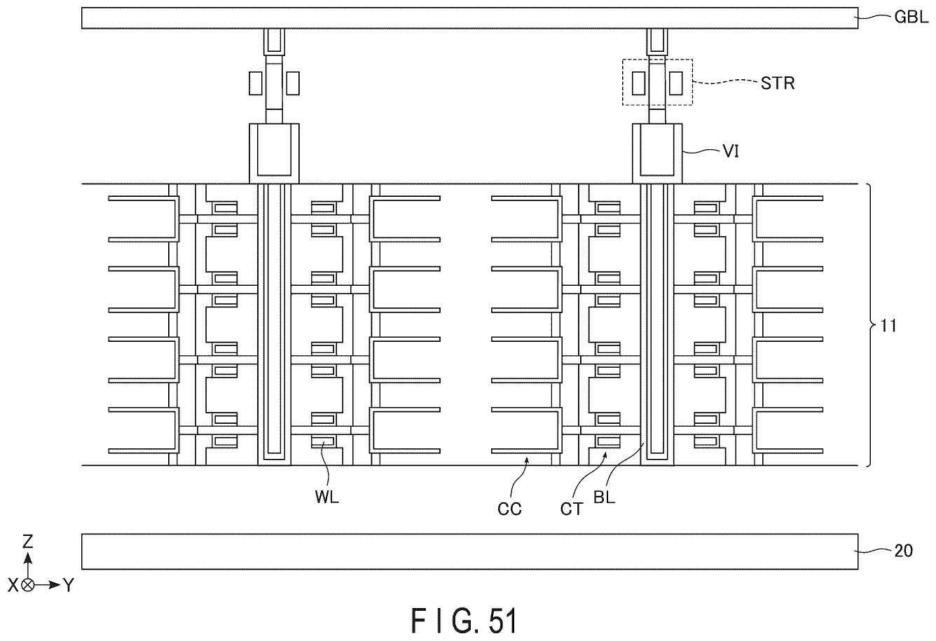

FIG. 51 is a cross-sectional view illustrating a third example of the layout of the bit line selection transistor in the memory device of the embodiment.

The memory cell array 11 is provided above the semiconductor substrate 20 (that is, the positive direction in the Z direction). A bit line selection transistor STR is provided above the memory cell array 11. A global bit line GBL is provided above the bit line selection transistor STR. That is, the bit line selection transistor STR is provided between the memory cell array 11 and the global bit line GBL. A plurality of bit lines BL in the memory cell array 11 is connected to the global bit line GBL via the contact plug VI and the bit line selection transistor STR.

One end of the cell transistor CT is connected to the cell capacitor CC. The other end of the cell transistor CT is connected to the bit line BL. One end of the bit line BL is connected to the global bit line GBL via the contact plug VI and the bit line selection transistor STR.

As described above, if the bit line selection transistor STR is arranged between the memory cell array 11 and the global bit line GBL arranged in the Z direction, it is possible to reduce a region on an XY plane necessary for forming the bit line selection transistor STR.

### 7. Effects According to Embodiments

According to the embodiment, it is possible to provide a memory device capable of being highly stacked. As a result, the storage capacity of the memory device can be increased. Alternatively, high integration of memory cells in the memory device is possible.

In general, in a case where a memory cell is formed using a stacked structure of epitaxially grown Si/SiGe and this memory cell is stacked on a substrate, there is a limit to epitaxial growth of Si/SiGe. Further, after a DRAM cell structure or the like is formed by processing an epitaxial stacked film of Si/SiGe, an epitaxial stacked film of Si/SiGe cannot be formed again on the DRAM cell structure or the like. Therefore, it may be difficult to achieve high stacking.

Therefore, in the present embodiment, for example, the memory cell MC is formed using a stacked structure of amorphous or polycrystalline silicon/silicon nitride (hereinafter, Si/SiN). The stacked structure of Si/SiN can be formed by a film forming apparatus such as CVD without using epitaxial growth. Therefore, there is no limit to the formation of the stacked structure as in the case of using epitaxial growth, and the memory cell MC can be highly stacked.

In the present embodiment, the cell transistor CT is formed after the cell capacitor CC of the memory cell MC is formed. That is, after the cell capacitor CC is formed, the semiconductor layer (that is, the channel layer) of the cell transistor CT is replaced with the sacrificial layer. Therefore, the cell transistor CT is not exposed to the thermal process at the time of forming the cell capacitor CC, and deterioration of the characteristics of the cell transistor CT can be prevented. In addition, since the semiconductor layer of the cell transistor CT is replaced with the sacrificial layer, a conductive oxide can be applied to the semiconductor layer of the cell transistor CT. Further, the bit line BL can be formed together with the formation of the semiconductor layer of the cell transistor CT. That is, a part of the bit line BL can be formed using a process for forming the semiconductor layer of the cell transistor CT.

In the description of the foregoing embodiment, the functional block may be implemented as any one of hardware and computer software, or a combination thereof. It is not essential that the functional blocks are distinguished as in the following examples. For example, some functions may be executed by a functional block different from the illustrated functional block. Further, the exemplary functional blocks may be divided into finer functional sub-blocks.

Although some embodiments of the present invention have been described, these embodiments have been presented as examples, and are not intended to limit the scope of the invention. These embodiments can be implemented in various other forms, and various omissions, substitutions, and changes can be made without departing from the spirit of the invention. These embodiments and modifications thereof are included in the scope and spirit of the invention and are included in the invention described in the claims and the equivalent scope thereof.

What is claimed is:

1. A memory device comprising:
a plurality of memory cells including a plurality of transistors stacked on a substrate in a first direction, and a plurality of capacitors stacked on the substrate in the first direction and connected to the plurality of transistors;
a bit line connected to the plurality of memory cells;
a word line connected to the plurality of memory cells; wherein
the plurality of transistors include semiconductor layers extending in a second direction parallel to the substrate and gate electrodes provided to face the semiconductor layers,
the bit line is connected to the semiconductor layers of the plurality of transistors and extends in the first direction,
the word line includes the gate electrodes of the plurality of transistors and extends in a third direction parallel to the substrate and intersecting the second direction, and
the semiconductor layers and the bit line include conductive oxide.

2. The memory device according to claim 1, wherein
the conductive oxide included in the bit line is continuously and integrally provided with the conductive oxide included in the semiconductor layers.

3. The memory device according to claim 1, wherein
the conductive oxide included in the bit line is provided in a sheet shape extending in the first direction, and
the bit line includes a conductive layer provided along conductive oxide of the sheet shape.

4. The memory device according to claim 1, further comprising a plate electrode connected to the capacitors stacked on the substrate.

5. The memory device according to claim 1, wherein the number of stacked capacitors is equal to or less than the number of stacked transistors.

6. The memory device according to claim 1, wherein the conductive oxide contains any one of In, Ga, Zn, Sn, Ti, Mo, and W.

7. The memory device according to claim 1, wherein the gate electrode of the transistor is provided to cover the semiconductor layer.

8. The memory device according to claim 1, wherein the gate electrode of the transistor is provided on any one of an upper surface and a lower surface of the semiconductor layer.

9. The memory device according to claim 1, wherein
the semiconductor layer of the transistor includes a first semiconductor layer and a second semiconductor layer, and
the gate electrode of the transistor is disposed between the first semiconductor layer and the second semiconductor layer.

10. The memory device according to claim 1, further comprising a transistor provided between the substrate and the memory cells and connected to the bit line.

11. The memory device according to claim 1, further comprising:
a first circuit provided between the substrate and the memory cells; and
a transistor provided between the first circuit and the memory cells and connected to the bit line.

12. The memory device according to claim 1, further comprising:
a global bit line provided above the memory cells; and
a transistor provided between the memory cells and the global bit line, and connected to the bit line and the global bit line.

13. A method for manufacturing a memory device including memory cells including transistors and capacitors, a word line, and a bit line, the method comprising:
alternately stacking first sacrificial layers and second sacrificial layers;
forming a first slit at one ends of the first sacrificial layers and the second sacrificial layers;
forming sacrificial semiconductor layers corresponding to semiconductor layers of the transistors on one end side of the second sacrificial layers by removing one end side of the first sacrificial layers and removing a part of one end side of the second sacrificial layers;
forming the word line crossing the sacrificial semiconductor layers;
forming a sacrificial bit line corresponding to the bit line at one end of the sacrificial semiconductor layer;
forming a second slit at the other ends of the first sacrificial layers and the second sacrificial layers;
removing the other end side of the second sacrificial layers and forming the capacitors at the other ends of the sacrificial semiconductor layers; and
replacing the sacrificial semiconductor layers and the sacrificial bit line with a semiconductor material layer.

14. The method for manufacturing the memory device according to claim 13, wherein
repeating processing from stacking the first sacrificial layers and the second sacrificial layers to forming the sacrificial bit line a plurality of times before forming the second slit; and
after the repeating, forming the capacitors, and replacing the sacrificial semiconductor layers and the sacrificial bit line with the semiconductor material layer.

15. The method for manufacturing the memory device according to claim 13, wherein the forming the capacitors comprises removing the second sacrificial layers from the second slit, and forming a layer containing conductive oxide at the other ends of the sacrificial semiconductor layers.

16. The method for manufacturing the memory device according to claim 14, further comprising forming an etching stop layer above the second sacrificial layers before repeating processing from stacking the first sacrificial layers and the second sacrificial layers to forming the sacrificial bit line a plurality of times.

17. The method for manufacturing the memory device according to claim 13, further comprising, after replacing the sacrificial semiconductor layers and the sacrificial bit line with the semiconductor material layer, forming a conductive layer on the semiconductor material layer in which a part of the sacrificial bit line is replaced.

18. The method for manufacturing the memory device according to claim 13, wherein the semiconductor material layer contains conductive oxide.

19. The method for manufacturing the memory device according to claim 18, wherein the conductive oxide contains any one of In, Ga, Zn, Sn, Ti, Mo, and W.

20. The method for manufacturing the memory device according to claim 13, wherein the first sacrificial layers contain silicon nitride, and the second sacrificial layers contain amorphous or polycrystalline silicon.
